(19) United States
(12) Patent Application Publication
(10) Pub. No.: US 2025/0228119 A1
(43) Pub. Date: Jul. 10, 2025

(54) ELECTROLUMINSECENT DEVICE, PRODUCTION METHOD THEREOF, AND DISPLAY DEVICE INCLUDING THE SAME

(71) Applicant: SAMSUNG ELECTRONICS CO., LTD., Suwon-si (KR)

(72) Inventors: Enjung KIM, Suwon-si (KR); Ha Il KWON, Suwon-si (KR); Hong Kyu SEO, Suwon-si (KR); SOONMIN CHA, Suwon-si (KR); SUNGWOO KIM, Suwon-si (KR)

(21) Appl. No.: 19/008,825

(22) Filed: Jan. 3, 2025

(30) Foreign Application Priority Data
Jan. 5, 2024 (KR) 10-2024-0002499

(51) Int. Cl. H10K 85/10; C09K 11/88; H10K 50/115; H10K 71/12; H10K 71/40

(52) U.S. Cl. CPC H10K 85/141; C09K 11/883; H10K 50/115; H10K 71/12; H10K 71/40

(57) ABSTRACT

An electroluminescent device and a method for making the device. The electroluminescent device includes a first electrode, a second electrode, a light emitting layer disposed between the first electrode and the second electrode, an electron transport layer disposed between the light emitting layer and the second electrode, and an organic layer. The light emitting layer includes a semiconductor nanoparticle, the electron transport layer includes a metal oxide nanoparticle, and the metal oxide nanoparticles have sizes of 1 nm or more and 50 nm or less. The organic layer includes a polymer, and the polymer includes a repeat unit with a hydroxy group.

### CROSS-REFERENCE TO RELATED APPLICATION

This application claims priority to Korean Patent Application No. 10-2024-0002499 filed in the Korean Intellectual Property Office on Jan. 5, 2024, and all the benefits accruing therefrom under 35 U.S.C. § 119, the content of which in its entirety is herein incorporated by reference.

### BACKGROUND

### 1. Field

The present disclosure relates to a light emitting (e.g., electroluminescent) device, a method for making the device, and a display device including the light emitting device.

### 2. Description of the Related Art

A semiconductor nanoparticle (e.g., a semiconductor nanocrystal particle) having a nanometer size may exhibit luminescence properties. For example, a quantum dot including a semiconductor nanocrystal may exhibit a quantum confinement effect. The light emission from the semiconductor nanoparticle may occur when an electron in an excited state resulting from light excitation or an applied voltage transitions from a conduction band to a valence band. The semiconductor nanoparticle may be configured to emit light of a desired wavelength region by adjusting a size of the semiconductor nanoparticle, a composition of the semiconductor nanoparticle, or a combination thereof.

A semiconductor nanoparticle may be used, for example, in a light emitting device (e.g., an electroluminescent device) or a display device including the electroluminescent device.

### SUMMARY

An embodiment provides a light emitting device that emits light, for example, by applying a voltage to the device that includes a nanostructure (e.g., a semiconductor nanoparticle such as a quantum dot) in an emission layer, for example with or without a separate irradiation light source.

An embodiment provides a display device (e.g., a quantum dot-light emitting diode (QD-LED) display device) that includes a plurality of semiconductor nanoparticles such as a quantum dots as a component of a light emitting layer in a pixel configuration (e.g., in a configuration of a blue pixel, a red pixel, a green pixel, or a combination thereof).

In an embodiment, an electroluminescent device includes; a first electrode and a second electrode (a thin film conductor) (for example, spaced apart, e.g., each electrode having a surface opposite the other), a light emitting layer disposed between the first electrode and the second electrode, an electron transport layer disposed between the light emitting layer and the second electrode, and an organic layer. The light emitting layer includes a semiconductor nanoparticle, and the electron transport layer includes a metal oxide nanoparticle. The metal oxide nanoparticles have a size of greater than or equal to about 1 nm and less than or equal to about 50 nm. The organic layer includes a polymer including a repeat unit with a hydroxy group.

The organic layer may be disposed on or over the electron transport layer, and optionally, on or over the second electrode.

The electron transport layer may have a first surface facing the light emitting layer and a second surface opposite to the first surface, and the organic layer may be disposed on or over (for example, directly on or being spaced apart therefrom) the second surface of the electron transport layer.

The organic layer may be disposed or positioned spaced apart from the electron transport layer and the second electrode. The organic layer may be disposed to face the electron transport layer and/or the second electrode. The second electrode may be disposed between the organic layer and the electron transport layer.

The second electrode may have a first surface facing a surface of the electron transport layer and a second surface opposite the first surface, and the organic layer may be spaced apart therefrom, and the organic layer may be disposed to face at least a portion (or the entire) of the surface of the electron transport layer and/or at least a portion (or the entire) of the second surface of the second electrode.

In an embodiment, the electroluminescent device may further include a container configured to accommodate at least the electron transport layer and the second electrode. The container may include a light transmitting member (for example, a light transmitting material or a light transmitting component). The container may further include an additional member (for example, bonded or linked to the light transmitting member) such as a sealing material. The container may be an encapsulation element for a stacked structure. The container or the light-transmitting member may include an organic material such as a polymer, an inorganic material such as glass, an organic and inorganic hybrid material, or a combination thereof. The container may be an integrated element including a single member or material. The container may be an element including a plurality of members or materials that are joined to form the container.

The organic layer may be disposed on a surface (for example, a surface facing the second electrode) of the container (or the light-transmitting member). The organic layer may be applied or coated on a surface of the container or the light-transmitting member.

The electroluminescent device may further include a hole auxiliary layer between the light emitting layer and the first electrode. The hole auxiliary layer may include a hole transport layer (e.g., including an organic compound), a hole injection layer, or a combination thereof. The organic material of the hole injection layer or the hole transport layer may include an arylamine compound such as TPD, an imidazole compound such as TPBi, a carbazole biphenyl compound such as CBP, a carbazole phenylamine compound such as TCTA, a naphthylbiphenyl diamine compound such as NPB, a polymer such as PEDOT:PSS, PVK, or TFB, or a combination thereof, but is not limited thereto.

The semiconductor nanoparticle may include a first semiconductor nanocrystal including zinc, selenium, and tellurium, and a second semiconductor nanocrystal including a zinc chalcogenide, the second semiconductor nanocrystal being different from the first semiconductor nanocrystal. The semiconductor nanoparticle may include a first semiconductor nanocrystal including (a Group Ill-V compound or an indium phosphide compound including) indium, phosphorus, and optionally zinc; and a second semiconductor nanocrystal including a zinc chalcogenide and different from the first semiconductor nanocrystal.

A size or an average size (hereinafter, referred to as “size”) of the semiconductor nanoparticle may be greater than or equal to about 4 nanometers (nm), greater than or equal to about 5 nm, greater than or equal to about 7 nm, greater than or equal to about 8 nm, greater than or equal to about 9 nm, or greater than or equal to about 10 nm. The size of the semiconductor nanoparticle may be less than or equal to about 30 nm, less than or equal to about 20 nm, less than or equal to about 15 nm, less than or equal to about 12 nm, or less than or equal to about 10 nm.

The semiconductor nanoparticle may have a core-shell structure that includes a core including the first semiconductor nanocrystal and a shell disposed on the core and including the second semiconductor nanocrystal.

The electron transport layer may be adjacent to (or disposed directly on) the light emitting layer.

A size or an average size (hereinafter, referred to as “size”) of the metal oxide nanoparticle may be greater than or equal to about 1 nm, or greater than or equal to about 3 nm. The size of the metal oxide nanoparticle may be less than or equal to about 50 nm, less than or equal to about 30 nm, less than or equal to about 20 nm, less than or equal to about 10 nm, or less than or equal to about 8 nm.

The metal oxide nanoparticle may include a zinc oxide (nanoparticle). The metal oxide nanoparticle may include zinc; and optionally a Group IIA metal, Zr, W, Li, Ti, Y, Al, Ga, In, Sn, Co, V, or a combination thereof. The metal oxide nanoparticle may further include an alkali metal. The metal oxide nanoparticle may include zinc, a Group IIA metal, and optionally an alkali metal.

The metal oxide nanoparticle may include a compound represented by Zn₁₋ₓMₓO, wherein, M is Mg, Ga, Ca, Zr, Co, W, Li, Ti, Y, Al, or a combination thereof, and 0≤x≤0.5. The x may be greater than or equal to about 0.01, greater than or equal to about 0.03, greater than or equal to about 0.05, greater than or equal to about 0.1, or greater than or equal to about 0.15. The x may be less than or equal to about 0.45, or less than or equal to about 0.4.

The polymer may include a repeat unit represented by Chemical Formula 1:

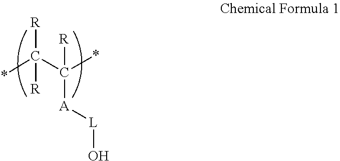

where A is a direct bond, —C(O)—, —O—, an ester (—C(O)O— or —OC(O)—), —C(O)NH—, —NH—, —S—, —S(O)—, or a combination thereof,
L is a direct bond, a substituted or unsubstituted (e.g., divalent) C1-C30, C2-C15, C3-C20, C4-C8, C5-C6, C1-10 aliphatic hydrocarbon group (e.g., an alkylene group or an alkenylene group), a substituted or unsubstituted C6-C20 arylene group (e.g., a phenylene group),
R are same or different and each independently hydrogen or a substituted or unsubstituted C1 to C30 (or C5 to C10) alkyl group, and
* is a portion that is bound to an adjacent atom (e.g., in a main chain).

The polymer may include a polyvinyl alcohol, a polyvinyl phenol, a polyhydroxyalkyl(meth)acrylate, a polyhydroxyalkyl(meth)acrylamide, or a combination thereof. The polymer may include (or may be) a copolymer or a homopolymer.

The polymer may have a (number or weight) average molecular weight of greater than or equal to about 500 g/mol, greater than or equal to about 1000 g/mol, greater than or equal to about 5000 g/mol, or greater than or equal to about 10,000 g/mol. The polymer may have a number or weight average molecular weight of less than or equal to about 5,000,000 g/mol, less than or equal to about 3,000,000 g/mol, or less than or equal to about 1,000,000 g/mol.

The polymer may be a water-soluble polymer. The polymer may have a solubility of greater than or equal to about 1 gram per liter (g/L), greater than or equal to about 10 g/L, or greater than or equal to about 30 g/L, with respect to water or an alcohol for example, at room temperature, e.g., at a temperature of about 20° C. to about 23° C. The solubility of The polymer with respect to water or the alcohol may less than or equal to about 5000 g/L, less than or equal to about 4000 g/L, less than or equal to about 3000 g/L, less than or equal to about 1500 g/L, less than or equal to about 1000 g/L, less than or equal to about 500 g/L, or less than or equal to about 200 g/L, for example, at room temperature, e.g., at a temperature of about 20° C. to about 23° C.

The polymer may exhibit, for example, a pH of greater than or equal to about 4.5 and less than or equal to about 8.5, or greater than or equal to about 5 and less than or equal to about 8.5, or less than or equal to about 7, or less than or equal to about 5.5, for example, as being dissolved in water, or C1-C10 alcohol.

The polymer, when analyzed by NMR, can exhibit a hydroxyl peak (e.g., three peaks) between 4-5 ppm.

The organic layer may have a thickness of greater than or equal to about 1 nm, greater than or equal to about 10 nm, greater than or equal to about 100 nm, greater than or equal to about 1 micrometer (um), greater than or equal to about 2 um, greater than or equal to about 3 um, greater than or equal to about 4 um, greater than or equal to about 5 um, greater than or equal to about 10 um, greater than or equal to about 100 um, or greater than or equal to about 1000 um. The thickness of the organic layer may be less than or equal to about 1 millimeter, less than or equal to about 900 um, less than or equal to about 100 um, less than or equal to about 50 um, less than or equal to about 35 um, less than or equal to about 10 um, less than or equal to about 9 um, or less than or equal to about 7 um.

The organic layer or the polymer may dissolve at least partially or entirely after being immersed in a first solvent comprising water, a C1-C10 alcohol (e.g., ethanol), dimethyl sulfoxide, an ether solvent, a ketone solvent, an ester solvent, or a mixture thereof.

The organic layer or the polymer may include a polyvinyl alcohol, a polyvinyl phenol, a polyhydroxyalkyl(meth)acrylate, a polyhydroxyalkyl(meth)acrylamide, or a combination thereof.

A temperature of the first solvent may be greater than or equal to about 25° C. and less than or equal to about 100° C., 50° C. or less, or 30° C. or less. The first solvent may include water; ethanol; a mixture of water and ethanol; a mixture of water and DMSO; or a mixture of ethanol and DMSO.

The organic layer or the polymer material may further include or may not include an additive. The additive may include an inorganic acid such as a sulfuric acid, a C2-50 carboxylic acid compound (e.g., represented by R(COOH)ₙ), a sulfinic acid compound (e.g., represented by R(SO₂H)ₙ), a sulfonic acid compound (e.g., represented by R(SO₃H)ₙ), or a combination thereof. In the formulae, the R is a substituted or unsubstituted C1 (or C6) to C50 aliphatic or aromatic hydrocarbon group, and the n is an integer of 1 to 10, 2 to 8, or 3 to 5. In an embodiment, the organic layer or the polymer material may not include the additive.

An amount of a cross-linked polymer in the organic layer or the polymer may be less than about 1 weight percent (wt %), or less than or equal to about 0.9 wt %, based on a total weight of the organic layer.

The organic layer may include or may not include a cross-linked polymer.

The second electrode may have a thickness of greater than about 10 nm, greater than or equal to 11 nm, or greater than or equal to about 15 nm. The second electrode may have a thickness of less than or equal to about 80 nm, less than or equal to about 60 nm, less than or equal to about 50 nm, or less than or equal to about 40 nm. The thin film conductor may include silver, aluminum, magnesium, tungsten, nickel, cobalt, platinum, palladium, calcium, LiF, gold, copper, or a combination thereof (e.g., alloy). The second electrode or the thin film conductor may include silver and magnesium.

The light emitting layer may be configured to emit first light.

The second electrode may be configured to exhibit a light transmittance of greater than or equal to about 25%, greater than or equal to about 35%, greater than or equal to about or 40% for the first light. The light transmittance may be less than or equal to about 90%, less than or equal to about 70%, or less than or equal to about or 55%.

The first electrode may be configured to reflect at least a portion of the first light.

In an embodiment, a method of making or producing an electroluminescent device includes:
forming a light emitting layer including a semiconductor nanoparticle on a first electrode;
forming an electron transport layer including a metal oxide nanoparticle on the light emitting layer;
forming a thin film conductor (or a second electrode) on the electron transport layer to obtain a stacked structure; and
conducting a post-treatment of the stacked structure with a polymer including a repeat unit with a hydroxy group (or an organic layer including the polymer),
wherein the post treatment includes
positioning the stacked structure with the polymer in a first space; and maintaining the first space at a post treatment temperature of greater than or equal to about 40° C. The post-treatment temperature may be less than or equal to about 200° C., less than or equal to about 180° C., or less than or equal to about 150° C.

The polymer may be in a form of a composition for forming the organic layer.

The details regarding the polymer and the organic layer are as described herein.

The method may further include providing a container to the stacked structure, and the container may be configured to define at least a portion of the first space. Details for the container are the same as described herein. In an embodiment, the container may be an oven or a chamber. In an embodiment, the container may be an encapsulation (encap) glass. The container may be an oven including a hollow chamber and an element configured to heat the chamber in a controlled way.

The method may further include preparing a polymer composition (e.g., a composition for forming the organic layer) including the polymer and a liquid vehicle (e.g., a solvent).

The method may include applying the polymer composition onto the electron transport layer (and, optionally, the second electrode).

The method may further include applying the composition on the electron transport layer (and, optionally, the second electrode).

The method may include applying the composition to a surface of the container in a manner that the composition or the organic layer can face the electron transport layer and/or the second electrode.

The method may further include removing at least a portion of the liquid vehicle from the applied organic layer forming composition.

The liquid vehicle may include water, a C1-10 alcohol, a sulfoxide solvent such as dimethyl sulfoxide, a nitrile solvent, an ester solvent, or a combination thereof. The liquid vehicle may include water, ethanol, methanol, propanol, acetonitrile, ethyl acetate, dimethyl sulfoxide, or a combination thereof.

The first space may be a closed space, for example, a sealed space or a hermetic or airtight space. A temperature of the post-treatment may be greater than or equal to about 45° C., greater than or equal to about 50° C., greater than or equal to about 70° C., or greater than or equal to about 90° C. and less than or equal to about 180° C., less than or equal to about 150° C., less than or equal to about 120° C., or less than or equal to about 100° C. The post-treatment may be performed for a predetermined time. The predetermined time may be greater than or equal to about 10 minutes, greater than or equal to about 30 minutes, greater than or equal to about 1 hour, greater than or equal to about 2 hours, greater than or equal to about 5 hours and less than or equal to about 10 days, or less than or equal to about 10 hours, less than or equal to about 3 hours.

The method may further include removing the container after the post-treatment.

The method may further include providing a conductive layer on the thin film conductor after the post-treatment to form a conductor thin film (or a second electrode) with an increased thickness.

In an embodiment, a display device may include the light emitting device (e.g., an electroluminescent device).

In an embodiment, an electronic device may include the light emitting device.

The display device or the electronic device may include (or may be) AR/VR device, a handheld terminal, a monitor, a notebook computer, a television, an electronic display board, a camera, an electronic display component for an automatic vehicle or an electric car.

According to an embodiment, a light emitting device may exhibit improved light emitting properties and lifespan characteristics. The device of an embodiment may exhibit improved stability by maintaining electroluminescence properties at a desired level even under high temperature exposure or under a storage environment for an extended period or time. The method of an embodiment may more readily enable mass production of a front-emission type light emitting device.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1A is a schematic cross-sectional view of an electroluminescent device according to an embodiment;

FIG. 1B is a schematic cross-sectional view of an electroluminescent device according to an embodiment;

FIG. 2A is a schematic cross-sectional view of an electroluminescent device according to an embodiment;

FIG. 2B is a schematic cross-sectional view of an electroluminescent device according to an embodiment;

FIG. 2C is a schematic cross-sectional view of an electroluminescent device according to an embodiment;

FIG. 3A is a schematic cross-sectional view of an electroluminescent device according to an embodiment;

FIG. 3B is a schematic cross-sectional view of an electroluminescent device according to an embodiment;

FIG. 3C is a schematic cross-sectional view of an electroluminescent device according to an embodiment;

FIG. 4 is a schematic cross-sectional view of an electroluminescent device according to an embodiment;

FIG. 5A is a schematic cross-sectional view of a light emitting device according to an embodiment;

FIG. 5B is a plane view of the light emitting device of FIG. 5A.

FIG. 6A illustrates a schematic cross-sectional view of a stacked structure for a post-treatment in a process of manufacturing a light emitting device according to an embodiment.

FIG. 6B shows a schematic cross-sectional view of the stacked structure obtained by the process wherein the stacked structure is removed from the container after the post-treatment in the process of manufacturing the light emitting device according to FIG. 6A and then a second electrode is formed and a new container (having no layer of the acid material).

FIG. 7 is a diagram schematically illustrating an example of post-treatment (using an oven or a chamber as a container) during a manufacturing process of a light emitting device according to an embodiment.

FIG. 8 is a schematic cross-sectional view of a light emitting device (RGB pixel) according to an embodiment.

FIG. 9 is a schematic plane view of a display panel according to an embodiment.

FIG. 10 is a schematic cross-sectional view showing a display panel of FIG. 9 taken along line IV-IV.

### DETAILED DESCRIPTION

Advantages and characteristics of this disclosure, and a method for achieving the same, will become evident referring to the following example embodiments together with the drawings attached hereto. However, the embodiments should not be construed as being limited to the embodiments set forth herein. Rather, these embodiments are provided so that this disclosure will be thorough and complete, and will fully convey the scope of the invention to those skilled in the art.

In order to clearly explain the present disclosure, parts irrelevant to the description are omitted, and the same reference numerals are assigned to the same or similar elements throughout the specification. In the drawings, the thickness of layers, films, panels, regions, etc., are exaggerated for clarity. And in the drawings, for convenience of description, the thickness of some layers and regions are exaggerated. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the term “cross-sectional” means a case in which a cross-section of a given object is cut, for example, in a substantially vertical direction and is viewed laterally.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

Hereinafter, values of a work function, a conduction band, or a lowest unoccupied molecular orbital (LUMO) (or valence band or highest occupied molecular orbital (HOMO)) energy level is expressed as an absolute value from a vacuum level. In addition, when the work function or the energy level is referred to be “deep,” “high” or “large,” the work function or the energy level has a large absolute value based on “0 electron volts (eV)” of the vacuum level, while when the work function or the energy level is referred to be “shallow,” “low,” or “small,” the work function or energy level has a small absolute value based on “0 eV” of the vacuum level.

As used herein, the average (value) may be mean or median. In an embodiment, the average (value) may be a mean average.

As used herein, the term “peak emission wavelength” is the wavelength at which a given emission spectrum of the light reaches its maximum.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and TI, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” includes Group VA and includes nitrogen, phosphorus, arsenic, antimony, and bismuth, but is not limited thereto.

As used herein, “Group VI” includes Group VIA and includes sulfur, selenium, and tellurium, but is not limited thereto.

As used herein, “metal” includes a semi-metal such as Si.

As used herein, a number of carbon atoms in a group or a molecule may be referred to as a subscript (e.g., C6-50) or as C6 to C50.

As used herein, when a definition is not otherwise provided, “substituted” refers to replacement of at least one hydrogen of a compound or a group for a corresponding group moiety including a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of a, e.g., one or more, hydrogen atoms from alkane, alkene, alkyne, or arene. In the hydrocarbon or hydrocarbon group, a, e.g., at least one, methylene may be replaced by an oxide moiety, a carbonyl moiety, an ester moiety, —NH—, or a combination thereof. Unless otherwise stated to the contrary, the hydrocarbon compound or hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group formed by removal of a, e.g., at least one, hydrogen from an arene (e.g., a phenyl or naphthyl group). In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, S, Si, P, or a combination thereof.

As used herein, when a definition is not otherwise provided, “alkoxy” refers to an alkyl group linked to oxygen (e.g., alkyl-O—) for example, a methoxy group, an ethoxy group, or a sec-butyloxy group.

As used herein, when a definition is not otherwise provided, “amine” is a compound represented by NR₃, wherein each R is independently hydrogen, a C1-C12 alkyl group, a C7-C20 alkylaryl group, a C7-C20 arylalkylene group, or a C6-C18 aryl group.

As used herein, “poly(meth)acrylate” refers to a polyacrylate, a polymethacrylate, or a combination thereof.

In an embodiment, “an alkali metal salt” of a polymeric acid (e.g., polyacrylic acid or polystryrenesulfonic acid) compound may include a partial alkali metal salt of a given polymeric acid, a full alkali metal salt of the polymeric acid, or a combination thereof.

As used herein, the expression “not including cadmium (or other harmful heavy metal)” may refer to the case in which a concentration of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or about zero. In an embodiment, substantially no amount of cadmium (or other toxic heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

Unless mentioned to the contrary, a numerical range recited herein is inclusive. Unless mentioned to the contrary, a numerical range recited herein includes any real number within the endpoints of the stated range and includes the endpoints thereof. As used herein, the upper and lower endpoints set forth for various numerical values may be independently combined to provide a range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±5% of the stated value.

As used herein, a nanoparticle is a structure having a, e.g., at least one, region or characteristic dimension with a nanoscale dimension. In an embodiment, a dimension (or an average dimension) of the nanostructure is less than or equal to about 500 nm, less than or equal to about 300 nm, less than or equal to about 250 nm, less than or equal to about 150 nm, less than or equal to about 100 nm, less than or equal to about 50 nm, or less than or equal to about 30 nm. In an embodiment, the nanoparticle may have any suitable shape. The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape such as at least two pods, or the like and is not limited thereto. The nanoparticle can be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy thereof by controlling a size of a nanocrystal acting as an emission center.

As used herein, the term “T50” is a time (hours, hr) the brightness (e.g., luminance) of a given device decreases to 50% of the initial brightness (100%) as, e.g., when, the given device is started to be driven, e.g., operated, at a predetermined initial brightness (e.g., 650 nit or 146 nit).

As used herein, the term “T90” is a time (hr) the brightness (e.g., luminance) of a given device decreases to 90% of the initial brightness (100%) as the given device is started to be driven at a predetermined initial brightness (e.g., 650 nit or 146 nit).

As used herein, the phrase “external quantum efficiency (EQE)” is a ratio of the number of photons emitted from a light emitting diode (LED) to the number of electrons passing through the device and can be a measurement as to how efficiently a given device converts electrons to photons and allows the photons to escape. The EQE can be determined by the following equation:

EQE=an efficiency of injection×a (solid-state) quantum yield×an efficiency of extraction.

wherein the efficiency of injection is a proportion of electrons passing through the device that are injected into the active region, the quantum yield is a proportion of all electron-hole recombination in the active region that are radiative and produce photons, the efficiency of extraction is a proportion of photons generated in the active region that escape from the given device.

As used herein, a maximum EQE is a greatest value of the EQE.

As used herein, a maximum luminance is the highest value of luminance for a given device.

As used herein, the phrase, quantum efficiency, may be used interchangeably with the phrase, quantum yield. In an embodiment, the quantum efficiency may be a relative quantum yield or an absolute quantum yield, for example, which can be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (PL) wavelengths thereof, but are not limited thereto.

A bandgap energy of a semiconductor nanoparticle may vary with a size and a composition of a nanocrystal. For example, as a size of the semiconductor nanoparticle increases, the bandgap energy of the semiconductor nanoparticle may become smaller, e.g., narrower, and the semiconductor nanoparticle may emit light of, e.g., having an, increased emission wavelength. A semiconductor nanocrystal may be used as a light emitting material in various fields of, e.g., such as in, a display device, an energy device, or a bio light emitting device.

A semiconductor nanoparticle based electroluminescent device (hereinafter, also referred to as a QD-LED) may emit light by applying a voltage and includes a semiconductor nanoparticle or a quantum dot as a light emitting material. A QD-LED, which uses a different emission principle than an organic light emitting diode (OLED), may exhibit light emission with more desirable optical properties, e.g., higher purity, colors (e.g., red, green, and blue) and improved color reproducibility, and therefore, may be the basis for a next generation display device. A method of producing a QD-LED may include a solution process, which may lower, e.g., reduce, a manufacturing cost. In addition, a semiconductor nanoparticle in a QD-LED may be based on an inorganic material, contributing to realization of increased display (light emission) stability over time. It is desirable to develop a technology capable of improving device physical properties and life span characteristics.

In the QD-LED of an embodiment, holes and electrons provided from the two electrodes (e.g., a cathode and an anode) and passing through several common layers may meet and combine in the emission layer (EML, Emitting layer, QD emission layer) to form excitons resulting in light emission. In an embodiment of the QD-LED, common layers may be provided between the light emitting layer and the electrode, e.g., to facilitate injection of holes and electrons as a voltage is applied, and thus the design of these common layers may have an effect on properties (e.g., optical or stability property) of the device.

For example, an electron transport layer may be required to have sufficient electron mobility to balance the hole-electron in the light emitting layer, and in this case, electrons can be efficiently moved from the electrode to the quantum dot light emitting layer. In addition, the electron transport layer may be required to have an appropriately deep HOMO energy level, sufficiently blocking holes coming from the quantum dot light emitting layer.

In addition, a quantum dot or a semiconductor nanoparticle exhibiting a desirable electroluminescent property may contain a harmful heavy metal such as cadmium (Cd), lead, mercury, or a combination thereof. Accordingly, it may be desirable to provide an electroluminescent device or a display device having a light emitting layer substantially free of such heavy metals.

In an embodiment, an electroluminescent device may be a device configured to emit a desired light by applying a voltage, for example, with or without a separate light source.

In an embodiment, a light emitting device (or a stacked structure) includes a first electrode (e.g., a hole injection conductor) 1 and a thin film conductor (e.g., an electron injection conductor or a second electrode) 5 spaced apart (e.g., facing each other); and an emission layer 3 disposed between the first electrode and the thin film conductor and including a semiconductor nanoparticle; and an electron transport layer or an electron auxiliary layer 4 including the electron transport layer between the emission layer 3 and the thin film conductor 5. The electron transport layer may include a metal oxide nanoparticle. The emission layer above may be configured to emit a first light by applying a voltage (e.g., between the first electrode above and the conductor thin film above).

In an embodiment, the electroluminescent device may further include an organic layer 6, 60. The organic layer may include a polymer. The polymer includes a repeat unit with a hydroxy group. The polymer may be a copolymer that includes a repeat unit with a hydroxy group.

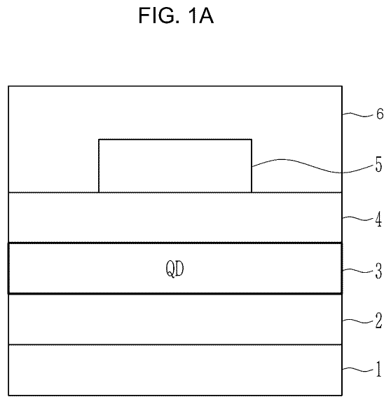

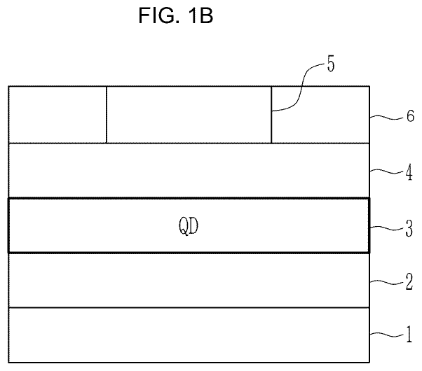

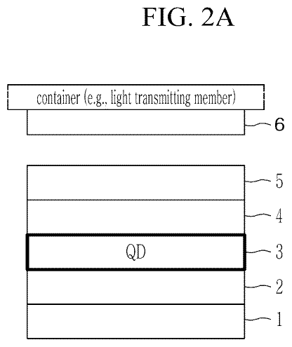

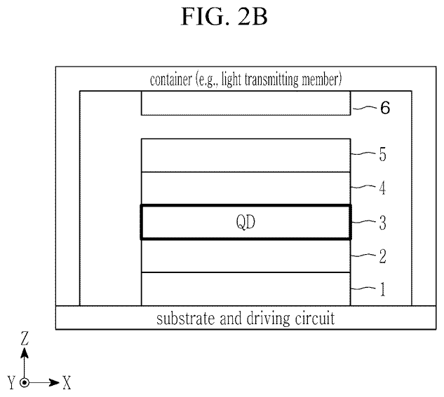

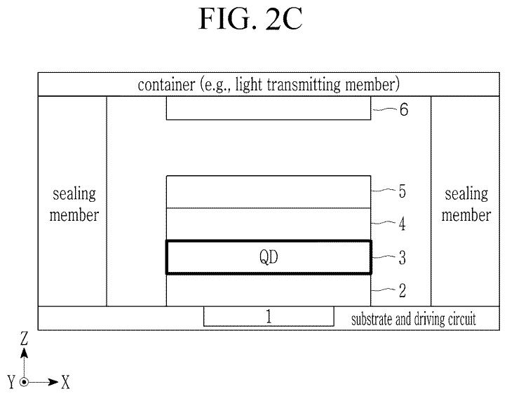

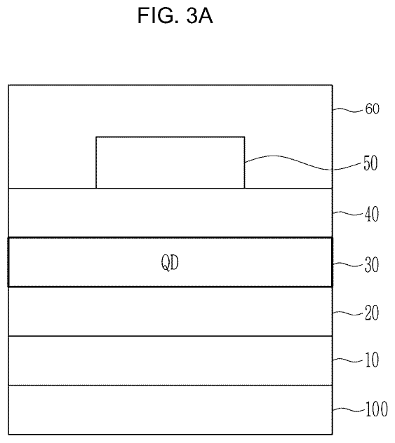

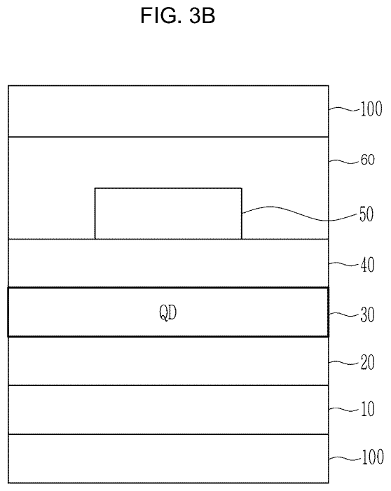

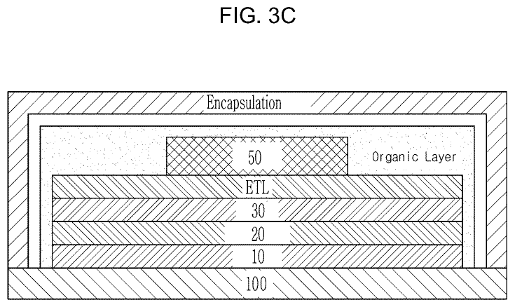

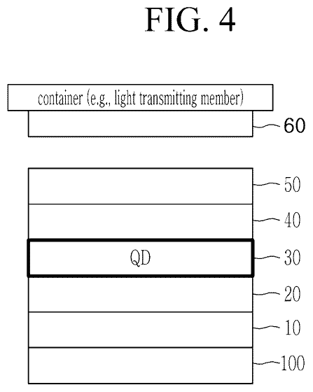

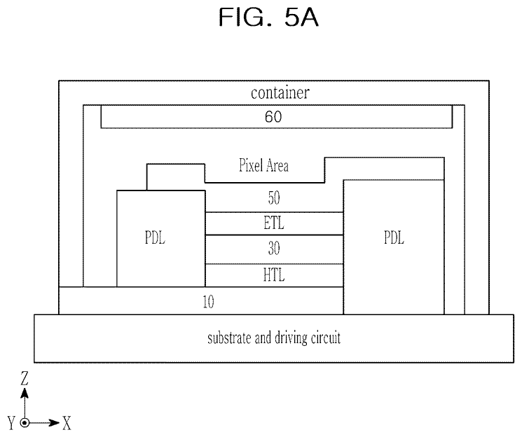

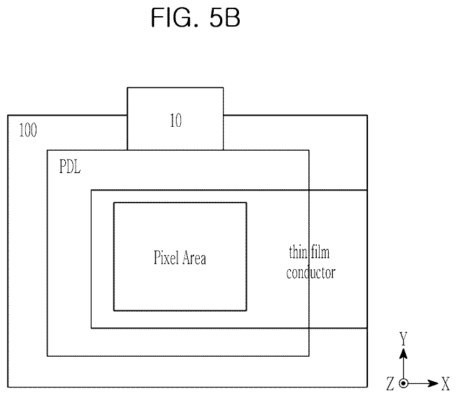

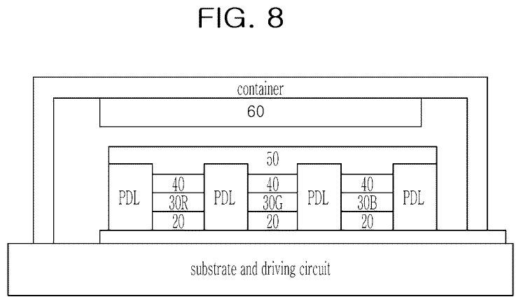

The electroluminescent device may further include a hole auxiliary layer 2, 20. The hole auxiliary layer may include a hole transport layer (HTL e.g., including an organic compound), a hole injection layer (HIL), or a combination thereof. (see: FIGS. 1A and 1B, FIGS. 2A, 2B, and 2C) In the electroluminescence device of an embodiment, the organic layer 6 may be disposed on the electron transport layer 4 and optionally on the second electrode. The organic layer 6 may be disposed adjacent to the electron transport layer and the second electrode 5 (see FIGS. 1A, 1B, and FIG. 3A, 3B, and FIG. 3C). The organic layer 6 may be included (disposed) (see FIG. 2A, 2B, and FIG. 8) as being spaced apart from the electron transport layer 4 and the second electrode 5, for example, in a non-contact manner or a remote manner (see FIG. 2A, FIG. 2C, FIG. 4, FIG. 5A, and FIG. 8).

The electroluminescent device of an embodiment may further include a container (e.g., a light transmitting member) that is configured to accommodate an electron transport layer and a conductor thin film or a second electrode; or at least a portion of a stacked structure further including a first electrode and a light emitting layer in addition to the electron transport layer and the conductor thin film. See, e.g., FIGS. 2B, 2C. The container may include a light transmitting member, and further include an additional member, a seal, or the like. The container may include a transparent member, a non-transparent member (e.g., an additional member such as a seal member), or a combination thereof (a both of them). A first surface of the container may face the second electrode, and the organic layer may be provided on the first surface of the container to be adjacent or in contact with the container or the light transmitting member. A first surface of the organic layer may be adjacent to the container, and a second surface opposite to the first surface may face the second electrode and/or the electron transport layer. (See, FIG. 2A, FIG. 2B, and FIG. 2C, FIG. 4, FIG. 5A, FIG. 8)

In an embodiment, an electroluminescent device capable of exhibiting improved lifespan and improved electroluminescence characteristics (e.g., device efficiency and luminance) is described herein. In the electroluminescent device of an embodiment a hole leakage through an electron auxiliary layer (e.g., an electron transport layer) may be substantially blocked, and thus the electroluminescent device of an embodiment may exhibit an increase in electron transport characteristics, thereby achieving improved electron-hole balance and deterioration of the material due to charging may be suppressed or prevented.

In the electroluminescent device of an embodiment, the organic layer or the polymer may be formed from a composition having a relatively low viscosity, and may not exhibit light absorption characteristics in a predetermined wavelength range (e.g., 320 nm to 440 nm), so it can be used, for example, without substantial limitation to a light emitting manner of the display device (e.g., can be used for both of a bottom emission type device and a top emission type device). In the light emitting device of an embodiment, the electron transport layer (ETL) can exhibit improved electron mobility, which may contribute to an improved hole-electron balance in the light emitting layer and can efficiently transfer electrons from the electrode to the light emitting layer.

In an electroluminescent device of an embodiment, the electron auxiliary layer (e.g., the electron transport layer) may have a HOMO energy level having a desired depth, and the occurrence of a trap level may be suppressed, for example, effectively blocking an undesired hole movement from the light emitting layer including a semiconductor nanoparticle such as a quantum dot to the second electrode.

In the electroluminescent device of an embodiment, the thin film conductor may also serve as a second electrode. The second electrode may include the thin film conductor. The first electrode or the second electrode may include (or may be) an anode or a cathode. In an embodiment, the first electrode may include a cathode (or anode) and the second electrode may include an anode (or cathode). In an embodiment, the second electrode includes an electron injection conductor, such as a cathode, and the first electrode includes a hole injection conductor, such as an anode.

In a display device including the light emitting device of an embodiment, the first electrode may be disposed on the (transparent) substrate 100, see, e.g., FIG. 3A, or the substrate and a driving circuit, FIG. 2C. In an embodiment, the first light emitted from the light emitting layer may pass through the second electrode and the first surface of the container and extracted out and from the device (e.g., in the Z direction). In an embodiment, the first light may be extracted through the (transparent) first electrode and optionally a substrate 100. The light emitting layer may be disposed in a pixel (or subpixel) in the display device (display panel) to be described later.

In the electroluminescent device of an embodiment, a light emitting layer 3, 30 may be disposed between a first electrode (e.g., anode) 1, 10 and a second electrode (e.g., cathode) 5, 50. The conductor thin film may be the second electrode or the second electrode may include the conductor thin film. The second electrode or the cathode 5, 50 may include an electron injection conductor. The anode 1, 10 may include a hole injection conductor. The work functions of the electron/hole injection conductors included in the cathode and the anode may be appropriately adjusted and are not particularly limited. For example, the cathode may have a small work function and the anode may have a relatively large work function, or vice versa.

The electron/hole injection conductor may include a metal-based material (e.g., a metal, a metal compound, an alloy, or a combination thereof) such as aluminum, magnesium, tungsten, nickel, cobalt, platinum, palladium, calcium, LiF, etc.; a metal oxide such as gallium indium oxide or indium tin oxide (ITO); or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The first electrode, the second electrode, or a combination thereof may be a patterned electrode.

The first electrode, the second electrode, or a combination thereof may be disposed on a (e.g., insulating) substrate 100 and optionally a driving circuit such as TFT. The substrate 100 may be a substrate including an insulating material. The substrate may include a glass; a polymer such as a polyester of polyethylene terephthalate (PET), polyethylene naphthalate (PEN), and the like, polycarbonate, and polyacrylate; a polysiloxane (e.g., polydimethylsiloxane (PDMS)); an inorganic material such as Al₂O₃ or ZnO; or a combination thereof but is not limited thereto. A thickness of the substrate may be appropriately selected taking into consideration a substrate material but is not particularly limited. The substrate may be a flexible substrate. The substrate may further include an area for a blue pixel, an area for a red pixel, an area for a green pixel, or a combination thereof.

The substrate 100 or the container (or the light transmitting member included in the container) may be optically transparent. The substrate 100 or the container (or the light transmitting member) may have a light transmittance of greater than or equal to about 50%, greater than or equal to about 60%, greater than or equal to about 70%, greater than or equal to about 80%, greater than or equal to about 85%, or greater than or equal to about 90% and less than or equal to about 100%, for example, less than or equal to about 99%, or less than or equal to about 95%. The substrate or the container (or the light transmitting member included in the container) may have a transmittance of greater than or equal to about 50%, greater than or equal to about 60%, greater than or equal to about 70%, greater than or equal to about 80%, greater than or equal to about 85%, greater than or equal to about 90%, greater than or equal to about 95%, or greater than or equal to about 99%, and less than or equal to about 100%, for example, less than or equal to about 99%, or less than or equal to about 95%, with respect to the light emitted from the semiconductor nanoparticle for example included in the light emitting layer. In an embodiment, the substrate or the container (or the light-transmitting member) may be opaque or reflective.

In an embodiment, a thin film transistor may be disposed in each region of the substrate, but it is not limited thereto. In an embodiment, a source electrode or a drain electrode of the thin film transistor may be electrically connected to the first electrode or the second electrode. In an embodiment, the light-transmitting electrode may be disposed on a (e.g., insulating) transparent substrate. The substrate 100 may be a rigid or a flexible substrate.

The electrode may include or be made of, for example, a metal oxide such as an indium tin oxide (ITO) or an indium zinc oxide (IZO), a gallium indium tin oxide, a zinc indium tin oxide; a metal nitride such as a titanium nitride; a conductive polymer such as a polyaniline; LiF/Mg:Ag; a metal thin film of a single layer or a plurality of layers; or a combination thereof. In an embodiment, the electrode (e.g., the first electrode and/or the second electrode) may include aluminum (Al), a lithium-aluminum (Li:Al) alloy, a magnesium-silver (Mg:Ag) alloy, lithium fluoride-aluminum (LiF:Al), gold, silver, or a combination thereof. A ratio of the alloy may be appropriately selected and is not particularly limited. The electrode may be formed by vacuum deposition, thermal deposition, sputtering deposition, or the like.

A thickness of each of the electrode (the first electrode, the second electrode, or a combination thereof) or a thickness of the thin film conductor is not particularly limited and may be appropriately selected taking into consideration a device efficiency and an emission type of the device (e.g., a top emission or a bottom emission). For example, the thickness of the electrode (or the thin film conductor) may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode (or the thin film conductor) may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm.

A light transmitting electrode or a non-light transmitting or non-transmissive electrode (e.g., a reflective electrode) may be formed by adjusting the composition and/or thickness of the electrode. In an embodiment, the non-transmissive electrode may include a metal layer (e.g., aluminum, silver, or the like) disposed between layers of a metal oxide (e.g., light-transmitting metal oxide) such as an indium tin oxide. In an embodiment, the light-transmitting electrode may include a light-transmitting metal oxide, a thin metal or alloy thin film, or a combination thereof. The light-transmitting electrode may include a transparent electrode and a translucent electrode.

In the electroluminescent device of an embodiment, the second electrode or the thin film conductor may have a thickness of greater than or equal to about 1 nm, for example, greater than or equal to about 5 nm, or greater than or equal to about 9 nm and less than 100 nm, less than or equal to about 99 nm, or less than or equal to about 95 nm. The thickness of the second electrode or thin film conductor may be greater than about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm. The thin film conductor may have a thickness of less than or equal to about 80 nm, less than or equal to about 60 nm, less than or equal to about 50 nm, or less than or equal to about 40 nm.

In the electroluminescent device of an embodiment, the second electrode or the thin film conductor may have a light transmittance for the first light that is greater than or equal to about 20%, greater than or equal to about 25%, greater than or equal to about 30%, greater than or equal to about 35%, greater than or equal to about 40%, greater than or equal to about 45%, greater than or equal to about 50%, greater than or equal to about 55%, greater than or equal to about 57%, greater than or equal to about 59%, greater than or equal to about 60%, greater than or equal to about 63%, greater than or equal to about 65%, greater than or equal to about 67%, greater than or equal to about 69%, greater than or equal to about 70%, greater than or equal to about 75%, greater than or equal to about 78%, greater than or equal to about 80%, greater than or equal to about 82%, greater than or equal to about 85%, or greater than or equal to about 89%. The light transmittance for the first light may be less than or equal to about 100%, less than or equal to about 99%, less than or equal to about 98%, less than or equal to about 97%, less than or equal to about 96%, less than or equal to about 95%, less than or equal to about 94%, less than or equal to about 93%, less than or equal to about 92%, less than or equal to about 91%, less than or equal to about 90%, less than or equal to about 89%, less than or equal to about 88%, less than or equal to about 87%, less than or equal to about 86%, less than or equal to about 85%, less than or equal to about 84%, less than or equal to about 83%, less than or equal to about 82%, less than or equal to about 80%, less than or equal to about 79%, less than or equal to about 76%, less than or equal to about 73%, less than or equal to about 68%, less than or equal to about 66%, less than or equal to about 64%, less than or equal to about 61%, less than or equal to about 60%, less than or equal to about 55%, less than or equal to about 50%, less than or equal to about 49%, less than or equal to about 48%, or less than or equal to about 47%.

In an embodiment of the light emitting device, the second electrode or the first electrode may be configured to reflect at least a portion (e.g., greater than or equal to about 50%, greater than or equal to about 60%, greater than or equal to about 70%, greater than or equal to about 80%, greater than or equal to about 90%, greater than or equal to about 95%, or greater than or equal to about 99%) of the first light. In an embodiment of the light emitting device, the second electrode or the first electrode may include a multi-layered structure, for example, having a structure of ITO/aluminum/ITO, ITO/Ag/ITO, Ag/ITO; a conductive metal electrode such as Ag, Al, Cu, Au, tungsten, nickel, cobalt, platinum; or a combination thereof.

The first electrode, the second electrode, or the conductive thin film (hereinafter, can be simply referred to as “electrode”) may include silver, aluminum, magnesium, tungsten, nickel, cobalt, platinum, palladium, calcium, LiF, gold, copper, or a combination thereof (e.g., alloy thereof). The electrode may include silver and magnesium, an alloy thereof, aluminum and magnesium, or an alloy thereof, or a combination thereof. The electrode may be an electrode that can be formed by a thermal deposition. In an embodiment, the electrode may exhibit a metal pore and/or a grain boundary in its cross-sectional view obtained by using a microscope or an electron microscope. In an embodiment, the electrode may not exhibit a metal pore and/or a grain boundary in its cross-sectional view obtained by using a microscope or an electron microscope.

In the electroluminescent device of an embodiment and the method of manufacturing the same, the thin film conductor may exhibit conductivity sufficient to serve as an electrode, and at the same time, the moisture and optionally the acid being supplied from the organic layer or the polymer may pass through the thin film conductor and reach the electron transport layer including a metal oxide nanoparticle, under the post-treatment conditions described herein. Without wishing to be bound by a theory, it is believed that the moisture and optionally the acid reaching the electron transport layer may modify a surface of the metal oxide nanoparticle, whereby a hydroxide ion (OH−) and a hydrogen ion (H+) may be supplied to the metal oxide nanoparticle in the electron transport layer to passivate a surface defect through a chemical reaction. The inclusion of the post-treated electron transport layer in the electroluminescent device of an embodiment can reduce a hole leakage current, which can be confirmed by a lower driving voltage and a higher efficiency of the device than the device prior to the post treatment. The inclusion of the post-treated electron transport layer in the electroluminescent device of an embodiment can increase the hole blocking performance and electron mobility of the electron transport layer, and this can contribute to the improvement of the brightness of the device. The inclusion of the post-treated electron transport layer in the electroluminescent device of an embodiment may alleviate a charging phenomenon at an interface between the light emitting layer and the electron transport layer, and the device of an embodiment may exhibit a reduced interfacial degradation and an increased lifespan.

The light emitting layer 3, 30 may be disposed between the first electrode 1, 10 and the second electrode 5, 50 (e.g., the anode 10 and the cathode 50). The light emitting layer may include a semiconductor nanoparticle (e.g., a blue light emitting nanoparticle, a red light emitting nanoparticle, or a green light emitting nanoparticle). The light emitting layer may include one or more (e.g., 2 or more or 3 or more and 10 or less) monolayers of the plurality of semiconductor nanoparticles.

The light emitting layer may be patterned. In an embodiment, the patterned light emitting layer may include a blue light emitting layer 30B disposed in the blue pixel, a red light emitting layer 30R disposed in the red pixel, a green light emitting layer 30G disposed in the green pixel, or a combination thereof. In an embodiment, the light emitting layer may include a red light emitting layer disposed in the red pixel and a green light emitting layer disposed in the green pixel. Each of the (e.g., red, green, or blue) light emitting layers may be (e.g., optically) separated from an adjacent light emitting layer by a partition wall. In an embodiment, partition walls or banks (e.g., a black matrix or a pixel defining layer, PDL) may be disposed between the red light emitting layer, the green light emitting layer, and the blue light emitting layer (see, FIG. 4 to FIG. 8, FIG. 10). In an embodiment, the red light emitting layer 30R, the green light emitting layer 30G, and the blue light emitting layer 30B may be optically isolated from each other.

In an embodiment, the light emitting layer 3, 30 or the semiconductor nanoparticle may not include cadmium. In an embodiment, the light emitting layer 3, 30 or the semiconductor nanoparticle may not include mercury, lead, or a combination thereof.

In an embodiment, the semiconductor nanoparticle may have a core-shell structure. In an embodiment, the semiconductor nanoparticle or the core-shell structure may include a core including a first semiconductor nanocrystal and a shell disposed on the core and including a second semiconductor nanocrystal having a composition different from that of the first semiconductor nanocrystal.

The semiconductor nanoparticle (or the first semiconductor nanocrystal, the second semiconductor nanocrystal, or a combination thereof) may include a Group II-VI compound, a Group III-V compound, a Group IV-VI compound, a Group IV element or compound, a Group I-III-VI compound, a Group II-III-VI compound, a Group I-II-IV-VI compound, or a combination thereof. In an embodiment, the light emitting layer or the semiconductor nanoparticle (e.g., the first semiconductor nanocrystal or the second semiconductor nanocrystal) may not include cadmium. In an embodiment, the light emitting layer or the semiconductor nanoparticle (e.g., the first semiconductor nanocrystal or the second semiconductor nanocrystal) may not include lead. In an embodiment, the light emitting layer or the semiconductor nanoparticle (e.g., the first semiconductor nanocrystal or the second semiconductor nanocrystal) may not include a combination of lead and cadmium.

The Group II-VI compound may be a binary element compound such as ZnS, ZnSe, ZnTe, ZnO, HgS, HgSe, HgTe, MgSe, MgS, or a combination thereof; a ternary element compound such as ZnSeS, ZnSeTe, ZnSTe, HgSeS, HgSeTe, HgSTe, HgZnS, HgZnSe, HgZnTe, MgZnSe, MgZnS, or a combination thereof; a quaternary element compound such as HgZnTeS, HgZnSeS, HgZnSeTe, HgZnSTe, or a combination thereof; or a combination thereof. The Group II-VI compound may further include a Group III metal.

The Group III-V compound may be a binary element compound such as GaN, GaP, GaAs, GaSb, AlN, AlP, AlAs, AlSb, InN, InP, InAs, InSb, or a combination thereof; a ternary element compound such as GaNP, GaNAs, GaNSb, GaPAs, GaPSb, AlNP, AlNAs, AlNSb, AlPAs, AlPSb, InNP, InNAs, InNSb, InPAs, InPSb, or a combination thereof; a quaternary element compound such as GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, or a combination thereof; or a combination thereof. The Group III-V compound may further include a Group II metal (e.g., InZnP).

The Group IV-VI compound may be a binary element compound such as SnS, SnSe, SnTe, PbS, PbSe, PbTe, or a combination thereof; a ternary element compound such as SnSeS, SnSeTe, SnSTe, PbSeS, PbSeTe, PbSTe, SnPbS, SnPbSe, SnPbTe, or a combination thereof; a quaternary element compound such as SnPbSSe, SnPbSeTe, SnPbSTe, or a combination thereof; or a combination thereof.

Examples of the Group I-III-VI compound may be CuInSe₂, CuInS₂, CuInGaSe, and CuInGaS, but are not limited thereto.

Examples of the Group I-II-IV-VI compound may be CuZnSnSe, and CuZnSnS, but are not limited thereto. Examples of I-III-VI semiconductor compounds may include a ternary element compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂; a quaternary element compound such as AgInGaS₂, AgInGaSe₂; or a combination thereof.

Examples of the Group I-II-IV-VI compound include, but are not limited to, CuZnSnSe and CuZnSnS.

The Group IV element or compound may include a single-element such as Si, Ge, or a combination thereof; a binary element compound such as SiC, SiGe, or a combination thereof; or a combination thereof.

Each element included in a multi-element compound such as a binary element compound, a ternary element compound, or a quaternary element compound may be present in the particle at a uniform concentration or at a non-uniform concentration. For example, the chemical formula described above means the types of elements included in the compound, and the stoichiometries among the elements in the compound may be different the recited chemical formula. For example, the chemical formula “AgInGaS₂” may include AgInₓGa₁₋ₓS₂ (x is a real number of greater than 0 and less than or equal to 1), but is not limited thereto.

In an embodiment, the semiconductor nanoparticle or the first semiconductor nanocrystal may include a metal including indium, zinc, or a combination thereof and a non-metal including phosphorus, selenium, tellurium, sulfur, or a combination thereof. In an embodiment, the second semiconductor nanocrystal may include a metal including indium, zinc, or a combination thereof, and a non-metal including phosphorus, selenium, tellurium, sulfur, or a combination thereof.

In an embodiment, a first semiconductor nanocrystal may include InP, InZnP, ZnSe, ZnSeS, ZnSeTe, or a combination thereof; the second semiconductor nanocrystal may include ZnSe, ZnSeS, ZnS, ZnTeSe, or a combination thereof. In an embodiment, the shell may include zinc, sulfur, and optionally selenium in the outermost layer.

In an embodiment, the semiconductor nanoparticle may emit blue or green light and may include a core including ZnSeTe, ZnSe, or a combination thereof and a shell including a zinc chalcogenide (e.g., ZnS, ZnSe, ZnSeS, or a combination thereof). An amount of sulfur in the shell may increase or decrease in a radial direction (from the core toward the surface), e.g., the amount of sulfur may have a concentration gradient wherein the concentration of sulfur varies radially (e.g., decreases or increases in a direction toward the core).

In an embodiment, the semiconductor nanoparticle may emit red or green light, the core may include InP, InZnP, or a combination thereof, and the shell may include a Group II metal including zinc and a non-metal including sulfur, selenium, or a combination thereof.

In an embodiment, as the semiconductor nanoparticle has a core-shell structure, on the interface between the core and the shell, an alloyed interlayer may be present or may not be present. The alloyed interlayer layer may include a homogeneous alloy or may have a concentration gradient. The gradient alloy may have a concentration gradient wherein the concentration of an element of the shell varies radially (e.g., decreases or increases in a direction toward the core).

In an embodiment, the shell may have a composition that varies in a radial direction. In an embodiment, the shell may be a multilayered shell including two or more layers. In a multilayered shell, adjacent two layers may have different compositions from each other. In a multilayered shell, a, e.g., at least one, layer may independently include a semiconductor nanocrystal having a single composition. In a multilayered shell, a, e.g., at least one, layer may independently have an alloyed semiconductor nanocrystal. In a multilayered shell, a, e.g., at least one, layer may have a concentration gradient that varies radially in terms of a composition of a semiconductor nanocrystal.

In an embodiment, in a semiconductor nanoparticle having a core-shell structure, a shell material may have a bandgap energy that is larger, e.g., greater, than that of the core. The materials of the shell may have a bandgap energy that is smaller, e.g., less, than that of the core. In the case of a multilayered shell, the bandgap energy of the outermost layer material of the shell may be greater than the bandgap energies of the core and the inner layer material of the shell (layers that are closer to the core). In the case of a multilayered shell, a semiconductor nanocrystal of each layer is selected to have an appropriate bandgap, thereby effectively showing, e.g., exhibiting, a quantum confinement effect.

The semiconductor nanoparticle according to an embodiment may include, for example, an organic ligand which is bonded or coordinated to a surface thereof.

An absorption/emission wavelength of the semiconductor nanoparticle may be controlled by adjusting the compositions, sizes, or a combination thereof of the semiconductor nanoparticle. The semiconductor nanoparticle included in the light emitting layer 3, 30 may be configured to emit light of a desired color. The semiconductor nanoparticle may include a blue light emitting semiconductor nanoparticle, a green light emitting semiconductor nanoparticle, or a red light emitting semiconductor nanoparticle.

In an embodiment, a maximum emission peak wavelength of the semiconductor nanoparticle or a light emission layer (or the light emitted from the electroluminescent device) may be in a wavelength range of from ultraviolet to infrared or longer, or a visible light range, for example, a green light range, a red light range, or a blue light range.

In an embodiment, an emission peak wavelength of the semiconductor nanoparticle or the light emitting layer (or the light emitted from the electroluminescent device) may be greater than or equal to about 300 nm, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The emission peak wavelength of the semiconductor nanoparticle or a light emission layer (or the light emitted from the electroluminescent device) may be less than or equal to about 1000 nm, less than or equal to about 900 nm, less than or equal to about 800 nm, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The emission peak wavelength of the semiconductor nanoparticle or a light emission layer (or the light emitted from the electroluminescent device) may be from about 500 nm to about 650 nm.

The semiconductor nanoparticle (or the light emitted from the electroluminescent device) may emit green light (for example, on an application of a voltage or irradiation with light) and a maximum emission peak wavelength thereof may be in the range of greater than or equal to about 500 nm (for example, greater than or equal to about 510 nm, or greater than or equal to about 515 nm) and less than or equal to about 560 nm, for example, less than or equal to about 540 nm, or less than or equal to about 530 nm.

The semiconductor nanoparticle (or the light emitted from the electroluminescent device) may emit red light, (for example, on an application of voltage or irradiation with light), and a maximum emission peak wavelength thereof may be in the range of greater than or equal to about 600 nm, for example, greater than or equal to about 610 nm and less than or equal to about 650 nm, or less than or equal to about 640 nm.

The semiconductor nanoparticle (or the light emitted from the electroluminescent device) may emit blue light, (for example, on an application of voltage or irradiation with light) and a maximum emission peak wavelength thereof may be greater than or equal to about 430 nm (for example, greater than or equal to about 450 nm, greater than or equal to about 455 nm, greater than or equal to about 460 nm, greater than or equal to about 465 nm) and less than or equal to about 480 nm (for example, less than or equal to about 475 nm, less than or equal to about 470 nm, or less than or equal to about 465 nm).

In an embodiment, the semiconductor nanoparticle may exhibit a luminescent spectrum (e.g., photo- or electro-luminescent spectrum) with a relatively narrow full width at half maximum. In an embodiment, in the photo- or electro-luminescent spectrum, the semiconductor nanoparticle may exhibit a full width at half maximum of less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum may be greater than or equal to about 10 nm, greater than or equal to about 15 nm, greater than or equal to about 20 nm, or greater than or equal to about 25 nm.

The semiconductor nanoparticle may exhibit (or may be configured to exhibit) a quantum efficiency (or quantum yield) of greater than or equal to about 10%, for example, greater than or equal to about 30%, greater than or equal to about 50%, greater than or equal to about 60%, greater than or equal to about 70%, greater than or equal to about 80%, greater than or equal to about 90%, or about 100%.

The semiconductor nanoparticle may have a size (or an average size, hereinafter, can be simply referred to as “size”) of greater than or equal to about 1 nm and less than or equal to about 100 nm, greater than or equal to about 2 nm and less than or equal to about 50 nm, or greater than or equal to about 3 nm and less than or equal to about 15 nm. The size may be a diameter or equivalent diameter converted by assuming a spherical shape from an electron microscope image when not spherical. The size may be calculated from a result of an inductively coupled plasma atomic emission spectroscopy (ICP-AES) analysis. In an embodiment, the semiconductor nanoparticle may have a size of from about 1 nm to about 50 nm, for example, from about 2 nm (or about 3 nm) to about 35 nm. In an embodiment, a size (or an average size) of the semiconductor nanoparticle may be greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, or greater than or equal to about 12 nm. In an embodiment, a size (or an average size) of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, or less than or equal to about 12 nm.

The shape of the semiconductor nanoparticle or the semiconductor nanostructure is not particularly limited. For example, the shape of the semiconductor nanoparticle may include, but is not limited to, a sphere, a polyhedron, a pyramid, a multi-pod shape, a hexahedron, a cube, a cuboid, a nanotube, a nanorod, a nanowire, a nanosheet, or a combination thereof.

The semiconductor nanoparticle may be prepared in an appropriate method. The semiconductor nanoparticle may be prepared for example by a chemical wet method wherein a nanocrystal particle may grow by a reaction between precursors in a reaction system including an organic solvent and an organic ligand. The organic ligand or the organic solvent may coordinate (with or to) a surface of the semiconductor nanocrystal to control the growth thereof.

In an embodiment, for example, the method of preparing the semiconductor nanoparticle having a core/shell structure may include obtaining the core; reacting a first shell precursor including a metal (e.g., zinc) and a second shell precursor including a non-metal element (e.g., selenium, sulfur, or a combination thereof) in the presence of the core in a reaction medium including an organic ligand and an organic solvent at a reaction temperature (e.g., of greater than or equal to about 180° C., greater than or equal to about 200° C., greater than or equal to about 240° C., or greater than or equal to about 280° C. and less than or equal to about 360° C., less than or equal to about 340° C., or less than or equal to about 320° C.) to form a shell including a second semiconductor nanocrystal on a core including a first semiconductor nanocrystal. The method may further include separating a core from a reaction system producing the same and dispersing the core in an organic solvent to obtain a core solution.

In an embodiment, in order to form the shell, a solvent and optionally, the first shell precursor and a ligand compound may be heated at a predetermined temperature (e.g., greater than or equal to about 100° C.) under vacuum (also referred to herein as vacuum-treated) and then, after introducing an inert gas into the reaction vessel, the mixture may be heat-treated again at a predetermined temperature (e.g., greater than or equal to 100° C.). Then, the core and the second shell precursor may be added to the mixture and heated at a reaction temperature. The shell precursors may be added at different ratios during a reaction time simultaneously or sequentially.

In the semiconductor nanoparticle of an embodiment, the core may be prepared in an appropriate manner. In an embodiment, the organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctyl phosphine) substituted with a, e.g., at least one (e.g., 1, 2, or 3), C6 to C22 alkyl group, a phosphine oxide (e.g., trioctylphosphine oxide) substituted with a (e.g., 1, 2, or 3) C6 to C22 alkyl group, a C12 to C22 aromatic ether such as phenyl ether or benzyl ether, or a combination thereof. A combination including more than one type of organic solvent may be used.

The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH or a combination thereof. Herein, R and R′ are each independently a substituted or unsubstituted, C3 or greater, C6 or greater, or C10 or greater and about C40 or less, C35 or less, or C25 or less, aliphatic hydrocarbon group (e.g., alkyl, alkenyl, alkynyl, etc.), a substituted or unsubstituted C6 to C40 aromatic hydrocarbon group (e.g., aryl group), or a combination thereof. In an embodiment, at least two different organic ligands may be used.

In an embodiment, after completing the reaction (for the formation of the core or for the formation of the shell), a nonsolvent is added to reaction products and a nanoparticle coordinated with the ligand compound may be separated. The nonsolvent may be a polar solvent that is miscible with the solvent used in the core formation reactions, shell formation reaction, or a combination thereof and is not capable of dispersing the prepared nanocrystals. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing nonsolvents, or a combination thereof. The semiconductor nanocrystal particles may be separated through centrifugation, sedimentation, or chromatography. The separated nanocrystals may be washed with a washing solvent, if desired. The washing solvent has no particular limit and may have a similar solubility parameter to that of the ligand and may, for example, include hexane, heptane, octane, chloroform, toluene, benzene, and the like.

The semiconductor nanoparticle of an embodiment may be non-dispersible or insoluble in water, the aforementioned nonsolvent, or a combination thereof. The semiconductor nanoparticles of an embodiment may be dispersed in the aforementioned organic solvent. In an embodiment, the aforementioned semiconductor nanoparticles may be dispersed in a substituted or unsubstituted C6 to C40 aliphatic hydrocarbon, a substituted or unsubstituted C6 to C40 aromatic hydrocarbon, or a combination thereof.

The prepared semiconductor nanoparticle may be treated with a halogen compound. By the treatment with the halogen compound, at least a portion of the organic ligand may be replaced with the halogen. The halogen treated semiconductor nanoparticles may include a reduced amount of the organic ligand. The halogen treatment may be carried out contacting the semiconductor nanoparticles with the halogen compound (e.g., a metal halide such as a zinc chloride) at a predetermined temperature of from about 30° C. to about 100° C. or from about 50° C. to about 150° C. in an organic solvent. The halogen-treated semiconductor nanoparticles may be separated using the nonsolvent described above.

In the electroluminescent device or the display device of an embodiment, a thickness of the light emitting layer may be appropriately selected. The light emitting layer may have a thickness of greater than or equal to about 5 nm, for example, greater than or equal to about 10 nm, greater than or equal to about 20 nm, or greater than or equal to about 30 nm and less than or equal to about 200 nm, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer may have a thickness of, for example, about 10 nm to about 150 nm, about 20 nm to about 100 nm, or about 30 nm to about 50 nm.

In an embodiment, the forming of the light emitting layer including the semiconductor nanoparticles may be performed by obtaining a coating liquid including semiconductor nanoparticles and an organic solvent (e.g., an alkane solvent such as octane, heptane, or the like, an aromatic solvent such as toluene, or a combination thereof) and applying or depositing the coating liquid on a substrate or charge auxiliary layer (e.g., a hole auxiliary layer) in an appropriate manner (e.g., by spin coating, inkjet printing, etc.). A type of the organic solvent for the coating liquid is not particularly limited and may be selected appropriately. In an embodiment, the organic solvent may include a substituted or unsubstituted aliphatic hydrocarbon, a substituted or unsubstituted aromatic hydrocarbon, a substituted or unsubstituted alicyclic hydrocarbon, an acetate solvent, or a combination thereof.

In an embodiment, the formation of the light emitting layer may further include contacting the film of the semiconductor nanoparticles with a metal halide (e.g., a zinc chloride)-containing organic solution (e.g., including an alcohol solvent). In an embodiment, the light emitting layer may include a first light emitting layer including a first semiconductor nanoparticle and a second light emitting layer including a second semiconductor nanoparticle, wherein the first semiconductor nanoparticle has a halogen (e.g., chlorine) exchanged surface and the second light emitting layer has an increased amount of an organic ligand. A halogen (e.g., chlorine) amount and an organic ligand amount of the light emitting layer may be controlled with an appropriate manner (e.g., a post treatment for the formed layer). In an embodiment, a thin film of the semiconductor nanoparticles having an organic ligand (e.g., having a carboxylic acid group) is formed, which is then treated with a solution including a metal halide (e.g., a zinc halide such as a zinc chloride in alcohol solvent) to control an amount of the organic ligand of the semiconductor nanoparticles in the thin film. The treated thin film may have an increased halogen amount, showing, e.g., exhibiting, a changed property (e.g., solubility) to, e.g., relative to, an organic solvent, and it may be possible to form a layer of semiconductor nanoparticles having a different amount of an organic ligand (e.g., a halogen treated semiconductor nanoparticle or a semiconductor nanoparticle with a ligand having a carboxylic acid group) on the treated thin film, subsequently.

In an embodiment, the light emitting layer may be a single layer or a multi-layered structure having at least two layers. In a multi-layered structure, adjacent layers (e.g., a first light emitting layer and a second light emitting layer) may be configured to emit a first light (e.g., green light, blue light, or red light). In a multi-layered structure, adjacent layers (e.g., a first light emitting layer and a second light emitting layer) may have the same or different composition, ligands, or a combination thereof. In an embodiment, the (multi-layered) light emitting layer may exhibit a halogen content that varies (increase or decrease) in a thickness direction. In an embodiment, in the (multi-layered) light emitting layer, the amount of the halogen may increase in a direction toward the electron auxiliary layer. In the (multi-layered) light emitting layer, the amount of the organic ligand may decrease in a direction toward the electron auxiliary layer. In the (multi-layered) light emitting layer, the content of the organic ligand may increase in a direction toward the electron auxiliary layer.

In an embodiment, the light emitting layer thus formed (or treated with the halogen solution) may be washed with an organic washing solvent (water or an organic solvent miscible with the water). A manner of the washing is not particularly limited and may be conducted by a spin and dry, a dipping, or a combination thereof.

The light emitting layer may be heat-treated. The heat treating may be carried out in air or in an inert gas atmosphere. A temperature of the heat treating may be greater than or equal to about 50° C., greater than or equal to about 70° C., greater than or equal to about 90° C., greater than or equal to about 100° C., greater than or equal to about 120° C., greater than or equal to about 150° C., greater than or equal to about 170° C., or greater than or equal to about 200° C. A temperature of the heat treating may be less than or equal to about 250° C., less than or equal to about 230° C., less than or equal to about 200° C., less than or equal to about 180° C., less than or equal to about 160° C., less than or equal to about 140° C., or less than or equal to about 130° C.

The electroluminescent device of an embodiment includes an electron auxiliary layer 4, 40 disposed on the light emitting layer 3, 30, for example, between the light emitting layer and the second electrode or the thin film conductor (hereinafter, “second electrode”) 5, 50. In the electron auxiliary layer 4, 40, transporting, injecting, or transporting and injecting of electrons may occur. The electron auxiliary layer 4, 40 includes an electron transport layer (ETL). The electron transport layer includes a (plurality of) metal oxide nanoparticles. The electron auxiliary layer 4, 40 may further include an electron injection layer, a hole blocking layer, or a combination thereof. The electron injection layer, the hole blocking layer, or a combination thereof may be disposed between the electron transport layer and the second electrode, but it is not limited thereto. In an embodiment, the hole blocking layer may be disposed between the electron injection layer and the electron transport layer. In an embodiment, the electron transport layer may be disposed between the electron injection layer and the hole blocking layer. The electron transport layer may be adjacent (e.g., directly adjacent or directly disposed on) the light emitting layer. In an embodiment, the light emitting layer 3, 30 may contact (be directly disposed on) the electron transport layer.

The metal oxide (nanoparticle) may include a zinc oxide. The metal oxide (nanoparticle) or the zinc oxide may include zinc; and optionally a Group IIA metal, Zr, W, Li, Ti, Y, Al, gallium, indium, tin (Sn), cobalt (Co), vanadium (V), or a combination thereof. The metal oxide (nanoparticle) or the zinc oxide may include zinc, a Group IIA metal, and optionally an alkali metal.

The metal oxide (nanoparticle) or the zinc oxide may include a compound represented by Zn₁₋ₓMₓO, wherein, M is Mg, Ga, Ca, Zr, Co, W, Li, Ti, Y, Al, or a combination thereof, and 0≤x≤0.5. The x may be greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. The x may be less than or equal to about 0.47, less than or equal to about 0.45, less than or equal to about 0.43, less than or equal to about 0.4, less than or equal to about 0.37, less than or equal to about 0.35, or less than or equal to about 0.3. The metal oxide or the zinc oxide may further include magnesium. The electron transport layer or the zinc oxide may include Zn₁₋ₓMgₓO (x is greater than or equal to 0, or greater than 0 and less than or equal to about 0.5, the x is the same as defined herein), ZnO, or a combination thereof. The zinc oxide may further include magnesium.

A size or an average size (hereinafter, referred to as “size”) of the metal oxide nanoparticle(s) may be greater than or equal to about 1 nm, greater than or equal to about 2 nm, greater than or equal to about 2.5 nm, greater than or equal to about 3 nm, or greater than or equal to about 3.5 nm and less than or equal to about 10 nm, less than or equal to about 9 nm, less than or equal to about 8 nm, less than or equal to about 7 nm, less than or equal to about 6 nm, less than or equal to about 5 nm, or less than or equal to about 4.5 nm. A size of metal oxide nanoparticle can be a diameter or an equivalent diameter. The equivalent diameter is the value obtained by converting the size of a non-spherical particle into the diameter of a spherical particle. The size of the nanoparticles can be measured by appropriate means such as electron microscopy analysis like TEM or XRD. In this specification, the size can refer to the size of individual particles or the average size of a particle population.

In an embodiment, the metal oxide nanoparticle (e.g., the zinc oxide nanoparticle) may be prepared in any proper method, which is not particularly limited. The preparation of the metal oxide nanoparticles may include a solgel reaction. In an embodiment, the zinc oxide (e.g., zinc magnesium oxide) nanoparticle may be prepared by placing a zinc compound (e.g., an organic zinc compound such as zinc acetate dihydrate) and optionally an additional metal compound (e.g., an additional organic metal compound such as magnesium acetate tetrahydrate) in an organic solvent (e.g., dimethylsulfoxide) in a flask to have a desired mole ratio and heating the same at a predetermined temperature (e.g., from about 40° C. to about 120° C., or from about 60° C. to about 100° C.) (e.g., in air), and adding a precipitation accelerator solution (for example, a solution of tetramethyl ammonium hydroxide pentahydrate and ethanol) at a predetermined rate with, e.g., while, stirring. The prepared zinc oxide nanoparticle (e.g., ZnₓMg₁₋ₓO nanoparticle) may be recovered from a reaction solution for example via centrifugation.

In an embodiment, the electron auxiliary layer or the electron transport layer may be prepared in a solution process. In an embodiment, the electron auxiliary layer or the electron transport layer may be prepared by dispersing a plurality of metal oxide nanoparticles in an organic solvent (for example, a polar solvent, a non-polar solvent, or a combination thereof) to obtain an electron transport layer precursor dispersion, which is then applied to a surface to form a film. The electron transport layer precursor dispersion may be applied to the light emitting layer. The solution process may further include removing the organic solvent from the formed film for example by evaporation. The organic solvent may include a C1 to C10 alcohol solvent or a combination thereof.

In an embodiment, a thickness of the electron transport layer (ETL) may be greater than or equal to about 3 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 21 nm, greater than or equal to about 22 nm, greater than or equal to about 23 nm, greater than or equal to about 24 nm, greater than or equal to about 25 nm, greater than or equal to about 26 nm, greater than or equal to about 27 nm, greater than or equal to about 28 nm, greater than or equal to about 29 nm, greater than or equal to about 30 nm, greater than or equal to about 31 nm, greater than or equal to about 32 nm, greater than or equal to about 33 nm, greater than or equal to about 34 nm, or greater than or equal to about 35 nm. The thickness of the electron transport layer may be less than or equal to about 90 nm, less than or equal to about 80 nm, less than or equal to about 70 nm, less than or equal to about 60 nm, less than or equal to about 50 nm, less than or equal to about 45 nm, less than or equal to about 40 nm, or less than or equal to about 35 nm.

The thickness of the electron injection layer, the hole blocking layer, or a combination thereof is not particularly limited and may be appropriately selected. A thickness of the electron injection layer, the hole blocking layer, or a combination thereof may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm and less than or equal to about 500 nm, less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

In an embodiment, a material for the electron injection layer, the hole blocking layer, or a combination thereof may include 1,4,5,8-naphthalene-tetracarboxylic dianhydride (NTCDA), bathocuproine (BCP), tris[3-(3-pyridyl)-mesityl]borane (3TPYMB), LiF, tris(8-hydroxyquinolinato)aluminum (Alq₃), tris(8-hydroxyquinolinato)gallium (Gaq3), tris(8-hydroxyquinolinato)indium (Inq₃), bis-(8-hydroxyquinolinato)zinc (Znq₂), bis[2-(2-hydroxyphenyl)benzothiazolato]zinc (Zn(BTZ)₂), bis(10-hydroxybenzo[H]quinolinato)beryllium (BeBq₂), 8-(4-(4,6-di(naphthalen-2-yl)-1,3,5-triazin-2-yl)phenyl)quinolone (ET204), 8-hydroxyquinolinato lithium (Liq), 2,2′,2″-(1,3,5-Benzinetriyl)-tris(1-phenyl-1-H-benzimidazole) (TPBi), an n-type metal oxide (e.g., ZnO, HfO₂, etc.), 8-(4-(4,6-di(naphthalen-2-yl)-1,3,5-triazin-2-yl)phenyl)quinolone:8-hydroxyquinolinato lithium (ET204:Liq), or a combination thereof, but is not limited thereto.

In the electron transport layer, the metal oxide nanoparticle may provide higher electron mobility than an organic semiconductor material, and the light emitting layer, for example, being combined with the electron transport layer including the metal oxide nanoparticle, may exhibit a desired level of an electroluminescent property. In addition, the semiconductor nanoparticle-based emission layer may be formed by a solution process, and the metal oxide nanoparticle-based electron transport layer may be formed on the emission layer by a solution process, thereby providing a relatively efficient and advantageous process for the making of a device.

The present inventors have found in their research that a combination of an electron auxiliary layer including metal oxide nanoparticles and a light emitting layer including semiconductor nanoparticles may not provide the desired level improvements both in electroluminescence properties and lifespan characteristics. For example, a metal oxide nanoparticle (e.g., a zinc magnesium oxide nanoparticle) may be grown through a sol-gel reaction involving a precursor (e.g., Zn(CH₃COO)₂, Mg(CH₃COO)₂) in the presence of a base. Without wishing to be bound by any theory, it is believed that various surface chemical species such as metal ions, for example, (Zn²⁺, Mg²⁺), O²⁻, OH⁻, CH₃COO⁻, may exist on a surface of a metal oxide nanoparticle as a result of the synthesis, and these surface chemical species may be a source of surface defects for the nanoparticle, acting as a defect level in the ETL. Without wishing to be bound by any theory, it is believed that the surface defect present on the metal oxide (e.g., ZnMgO) particle may have an energy level near the HOMO level of the quantum dot or the semiconductor nanoparticle, and therefore, may serve as a trap site for holes and may cause an increase in leakage current.

The metal oxide nanoparticle in the electron auxiliary layer or the electron transport layer may include various defects occurring in its manufacturing process and the film formation process, and these defects may provide various levels within the nanoparticles to be used as a passage for a hole movement, and therefore, a metal oxide nanoparticle-based electron transport layer may exhibit a reduced hole blocking performance or relatively high hole leakage current, which may adversely affect the electroluminescence property (e.g., a luminous efficiency) of the device.

In addition, without wishing to be bound by any theory, surface defects that are possibly present on or in the metal oxide nanoparticle may cause an unwanted charge accumulation at an interface between the electron transport layer and the light emitting layer or in the electron transport layer. This accumulation of charges can lead to unwanted charging (e.g., within the electron transport layer or at the interface between the light emitting layer and the electron transport layer) and can cause a decrease in the luminance or lifespan of QD-LED devices.

The electroluminescent device of an embodiment or a method of manufacturing the same includes the adoption of an organic layer or a polymer material as described herein, or the adoption of an organic layer forming composition and an electron transport layer containing the metal oxide nanoparticles may be post-treated as described herein. The electroluminescent device of an embodiment including the post-treated electron transport layer can exhibit improved electroluminescence properties and life characteristics. In the post-treatment according to the method of an embodiment, moisture and/or an acid component can easily diffuse into the electron transport layer (in a contact manner or in a remote manner), and the electron transport layer can be readily used in both a bottom emission type and a front emission type device.

Without wishing to be bound by any theory, it is believed that in the post-treatment of an embodiment with the organic layer (or the polymer material) present and the conductor thin film (or the second electrode), the (diffused) moisture (and optionally acid) may induce the modification (e.g., a surface modification or a surface chemical reaction) of a metal oxide nanoparticle contained on or within the electron transport layer. This surface modification can passivate defects on the nanoparticle surface, and by improving the electrical properties of the metal oxide, the metal oxide nanoparticle as modified can exhibit conductivity increased to a desired degree, and when applied to the electron transport layer, it may exhibit effectively reduced hole leakage current and effectively reduced charge accumulation, and thereby charging issues or problems can be suppressed or alleviated. Accordingly, the electroluminescence device of an embodiment can exhibit an extended lifespan and improved efficiency.

The present inventors have also found that following the thermal treatment at an elevated temperature for a predetermined time, e.g., during a manufacturing step, an electroluminescent device may exhibit a (significant or substantial) change (e.g., decrease) in electroluminescent performance and/or the driving voltage for the device for a predetermined luminance can significantly increase. However, an electroluminescent device according to an embodiment is less sensitive to the higher temperatures and, in fact, quite surprisingly exhibits improved electroluminescent properties following a heat treatment at an elevated temperature for a predetermined time, i.e., the very opposite effect a person of ordinary skill would expect to encounter. In other words, an electroluminescent device according to an embodiment exhibits a relatively small, if any, increase in the driving voltage following exposure to high temperatures at a predetermined luminance.

In the electroluminescent device of an embodiment, an organic layer or a polymer may be provided on or over the electron transport layer (and, optionally the second electrode). The organic layer may include a polymer, and the polymer includes a repeat unit having a hydroxy group. In an embodiment, the introduction of the organic layer or the polymer as described herein can prevent or suppress the electroluminescent device from exhibiting a substantial or significant decrease in an electroluminescent property and/or a sharp increase in a driving voltage of the device even after the device is stored at an elevated temperature for an extended period of time.

In an embodiment, the electron transport layer or the electron auxiliary layer may include a first surface facing the light emitting layer and an opposite second surface, and the organic layer or the polymer may be disposed on at least a portion of or all of the second surface of the electron transport layer or the electron auxiliary layer. In an embodiment, the second electrode includes a first surface facing the electron transport layer and an opposite second surface, and the organic layer or the polymer may be disposed on at least a part or all of the second surface of the second electrode.

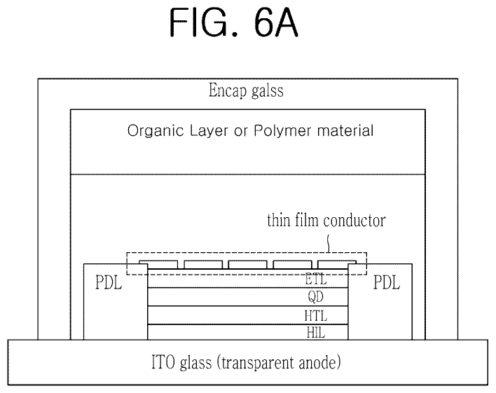

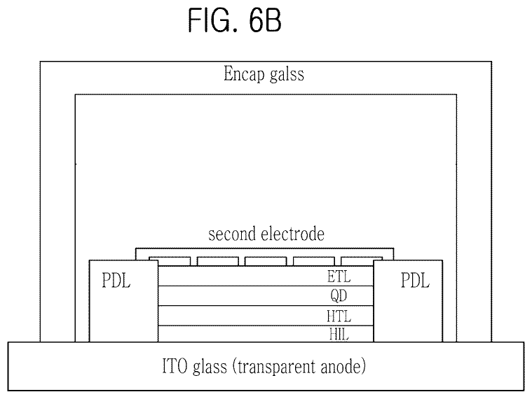

In an embodiment, the organic layer or the polymer may be in direct contact with the second surface of the electron transport layer and the second surface of the second electrode. (See, FIG. 1A, FIG. 1B, FIG. 3A, FIG. 3B, FIG. 3C, and FIG. 6B) In an embodiment, the organic layer or the polymer may be spaced apart from the electron transport layer or the second electrode, and may be disposed to face the electron transport layer or the second electrode. The electroluminescence device of an embodiment may further include a container configured to receive at least a portion of or the entire of a stacked structure including the first electrode, the emission layer, the electron transport layer, and the second electrode (or the conductor thin film), and the organic layer or the polymer may be disposed on a surface of the container (see FIG. 2A, FIG. 2B, FIG. 2C, FIG. 4, FIG. 5A, and FIG. 8).

The organic layer or the polymer material may be positioned to face (a surface of) the thin film conductor. The organic layer or the polymer material may be positioned to face the electron transport layer. The second electrode or the thin film conductor may be disposed between the organic layer (or the polymer) and the electron transport layer.

Without wishing to be bound by any theory, the hydrogen ion and/or the moisture provided by the organic layer or the polymer material may passivate a defect on a surface of the metal oxide nanoparticle, for example, by a chemical reaction to remove a trap site, suppressing a leakage current of holes generated through the trap site of the metal oxide (e.g., ZnMgO) nanoparticle, and/or enhancing a hole blocking ability of the metal oxide-based electron transport layer. Without wishing to be bound by any specific theory, it is believed that the electroluminescent device of an embodiment can show an increased external quantum efficiency (EQE) because the post-treatment may result in a more efficient hole-electron combination than presently known technology structures using known methods of manufacturing, e.g., steps that may include thermal treatments at elevated temperatures for an extended period of time.

In addition, the post-treatment may provide the surface modification of the metal oxide nanoparticle, whereby reducing the trap site, the charge accumulation at the trap site, and, as a result, the unwanted charging in the device can be prevented or suppressed. In addition, when being driven at a desired voltage for a long time, the device of an embodiment may exhibit a reduced/suppressed deterioration of the semiconductor nanoparticle or the ETL material (e.g., the metal oxide nanoparticle), and thus may exhibit an improved (e.g., extended) device lifespan.

The polymer may include a repeat unit represented by Chemical Formula 1:

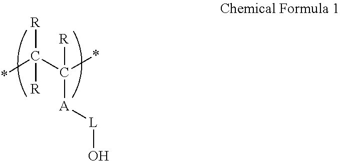

wherein A is a direct bond, —C(O)—, —O—, an ester (e.g. —C(O)O— or —OC(O)—), —C(O)NH—, —NH—, —S—, —S(O)—, or a combination thereof, and L is a direct bond, a substituted or unsubstituted divalent C1 to C30, C2-C15, C3-C10 aliphatic hydrocarbon group (e.g., an alkylene group, an alkenylene group), a substituted or unsubstituted C6-C20 or C8-C15 arylene group (e.g., a phenylene group), and R are the same or different and each independently hydrogen, or a substituted or unsubstituted C1 to C30 (or C5 to C10) alkyl group, and * is a portion linked to an adjacent atom (or adjacent repeat unit) (e.g., in the main chain).

In the polymer of an embodiment, both A and L in Chemical Formula 1 may be a direct bond.

In the polymer of an embodiment, A of Chemical Formula 1 may be an ester group (e.g. —C(O)O— or —OC(O)—), —C(O)—, or C(O)NH, and L of Chemical Formula 1 may be a substituted or unsubstituted divalent C1 to C30, C2-C15, or C3-C10 aliphatic hydrocarbon group (e.g., an alkylene group such as a propylene group, an ethylene group, a methylene group, a butylene group, a pentylene group, etc.; an alkenylene group).

In the polymer of an embodiment, A of Chemical Formula 1 may be a direct bond, and L of Chemical Formula 1 may be a substituted or unsubstituted C6-C20 arylene group (e.g., a phenylene group).

The polymer may be a copolymer having different repeat units. In addition to the repeat unit represented by Chemical Formula 1, the copolymer may further include an additional repeat unit, for example, a (meth)acrylate repeat unit, a (meth)acrylic acid repeat unit, or combinations thereof.

The polymer may include a polyvinyl alcohol or its copolymer; a polyvinylphenol or its copolymer; a polyvinylphenol-(co)(meth)acrylate; a polyhydroxyalkyl (meth)acrylate or its copolymer; a polyhydroxyalkyl (meth)acrylamide or its copolymer; or combinations thereof.

The polymer may be a hydrophilic polymer. The polymer may be soluble in water or in an organic solvent miscible with water (e.g., a C1-C10 or C2-C5 alcohol, DMSO). The polymer may be a water-soluble polymer

The polymer may include a polyvinyl alcohol. The polymer may be a non-gelled polymer. The polymer may be a linear polymer. The polymer may be a copolymer. The polymer may be a homopolymer. The polymer may include a first repeat unit (a unit derived from vinyl alcohol) represented by Chemical Formula 2 or Chemical Formula 2-1 and optionally a second repeat unit (a unit derived from a vinyl acetate) represented by Chemical Formula 3 or Chemical Formula 3-1:

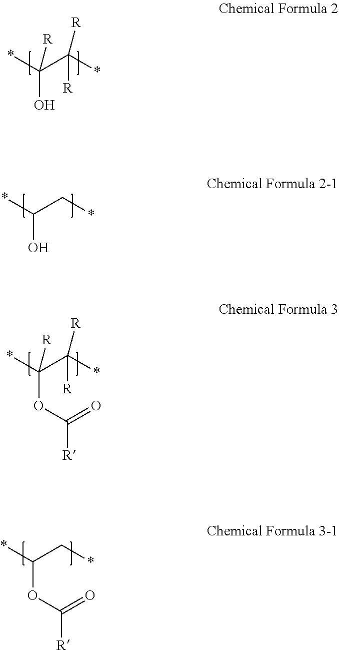

In the above formulas, * is a portion linked to an adjacent repeat unit, R are the same or different and each independently hydrogen or a substituted or unsubstituted C1 to C30 (or C5 to C10) alkyl group, and R′ is a substituted or unsubstituted C1-C10 (C2-C5) alkyl group.

In the polymer (or the polyvinyl alcohol), a mole percentage of the first repeat unit relative to the total content (moles) of the first and second repeat units (e.g., the degree of hydrolysis of the polymer) may be greater than or equal to about 50%, greater than or equal to about 55%, greater than or equal to about 60%, greater than or equal to about 65%, greater than or equal to about 70%, greater than or equal to about 75%, greater than or equal to about 80%, greater than or equal to about 85%, greater than or equal to about 90%, greater than or equal to about 95%, or greater than or equal to about 99%. The degree of hydrolysis of the polymer may be in the range of from about 78% to 100%, 80% to 99%, 82% to 98%, 85% to 95%, or a combination thereof.

The polymer (e.g., the polyvinyl alcohol) or its copolymer can be synthesized by various synthetic methods or can be commercially available.

The polymer may include a repeat unit represented by Chemical Formula 4 or Chemical Formula 4-1 or a polyvinyl phenol or a copolymer thereof including the repeat unit represented by Chemical Formula 4 or Chemical Formula 4-1:

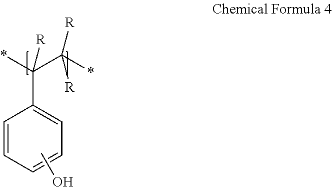

In the above formula, R are the same or different and each independently hydrogen or a substituted or unsubstituted C1 to C30 (or C5 to C10) alkyl group and * is a portion linked to an adjacent repeat unit. The phenyl group of Chemical Formula 4 or Chemical Formula 4-1 may have an additional substituent in addition to the hydroxy group and types of the additional substituent may be referred to the definition about the substituent described herein.

The polyvinyl phenol or a copolymer thereof may be synthesized by various synthesis methods or may be obtained commercially.

The polymer may include a repeat unit represented by Chemical Formula 5 or Chemical Formula 5-1; or a polyhydroxyalkyl (meth)acrylate or a copolymer thereof including the repeat unit represented by Chemical Formula 5 or Chemical Formula 5-1:

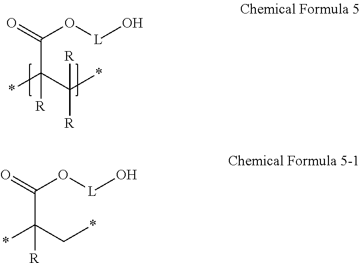

wherein R are the same or different and each independently hydrogen or a substituted or unsubstituted C1 to C30 (or C5-C10) alkyl group, and L is a substituted or unsubstituted C1 to 10 alkylene group (e.g., a methylene group, an ethylene group, a propylene group, a butylene group, a pentylene group, etc.), and * is a portion linked to an adjacent repeat unit.

The polyhydroxyalkyl(meth)acrylate or a copolymer thereof may be synthesized by various synthesis methods or commercially obtained.

The polymer has a solubility of greater than or equal to about 1 g/L, greater than or equal to about 5 g/L, greater than or equal to about 10 g/L, greater than or equal to about 15 g/L, greater than or equal to about 20 g/L, greater than or equal to about 33 g/L, greater than or equal to about 50 g/L, greater than or equal to about 55 g/L, greater than or equal to about 65 g/L, greater than or equal to about 70 g/L, greater than or equal to about 85 g/L, greater than or equal to about 100 g/L, greater than or equal to about 150 g/L, greater than or equal to about 200 g/L, greater than or equal to about 250 g/L, or greater than or equal to about 300 g/L with respect to water or alcohol. The polymer has a solubility of less than or equal to about 5000 g/L, less than or equal to about 4000 g/L, less than or equal to about 3000 g/L, less than or equal to about 1000 g/L, less than or equal to about 800 g/L, less than or equal to about 600 g/L, less than or equal to about 500 g/L, less than or equal to about 400 g/L, less than or equal to about 350 g/L, less than or equal to about 200 g/L, less than or equal to about 130 g/L, less than or equal to about 90 g/L, or less than or equal to about 80 g/L, with respect to water or alcohol. The polymer may be a water-soluble polymer.

The polymer may be water-soluble. In an embodiment, the water-soluble polymer can form a solution (e.g., an aqueous solution or an alcohol solution) with a polymer concentration of greater than or equal to about 5 wt %, greater than or equal to about 10 wt % based on a total weight of the solution (e.g., at 25° C. or at a temperature below 80° C.).

The polymer contains hydroxy groups within a repeat unit, which can be confirmed by an appropriate analysis. In an embodiment, the polymer can exhibit hydroxyl peaks (e.g., three peaks) between about 4 ppm to about 5 ppm as confirmed by an NMR analysis.

The polymer, as dissolved in water or alcohol, can exhibit a pH of greater than or equal to about 4.5, greater than or equal to about 5, greater than or equal to about 5.5, greater than or equal to about 6, greater than or equal to about 6.5, greater than or equal to about 7, greater than or equal to about 7.5, or greater than or equal to about 7.8, greater than or equal to about 8, greater than or equal to about 8.2, and less than or equal to about 9, less than or equal to about 8.7, less than or equal to about 8.5, less than or equal to about 8.3, less than or equal to about 8, less than or equal to about 7.6, less than or equal to about 7.2, or less than or equal to about 6.8. In the solution (e.g., an aqueous or alcohol solution), the concentration of the polymer can be from about 5 wt % to about 80 wt %, from about 10 wt % to about 75 wt %, from about 15 wt % to about 70 wt %, from about 18 wt % to about 65 wt %, from about 20 wt % to about 60 wt %, from about 25 wt % to about 55 wt %, from about 30 wt % to about 50 wt %, or combinations thereof.

The polymer may be soluble or insoluble in a C1 to C5 alcohol (e.g., ethanol). In an embodiment, the polymer can be soluble in a C1 to C5 alcohol (e.g., ethanol), DMSO, water, or combinations thereof.

In an embodiment, the polymer (or the copolymer) may have an average (e.g., a weight average or a number average) molecular weight (unit: g/mol) of greater than or equal to about 50, greater than or equal to about 80, greater than or equal to about 100, greater than or equal to about 150, greater than or equal to about 200, greater than or equal to about 250, greater than or equal to about 300, greater than or equal to about 350, greater than or equal to about 400, greater than or equal to about 450, greater than or equal to about 500, greater than or equal to about 550, greater than or equal to about 600, greater than or equal to about 650, greater than or equal to about 700, greater than or equal to about 750, greater than or equal to about 800, greater than or equal to about 900, greater than or equal to about 1000, greater than or equal to about 1100, greater than or equal to about 1200, greater than or equal to about 1300, greater than or equal to about 1400, greater than or equal to about 1500, greater than or equal to about 1600, greater than or equal to about 1700, greater than or equal to about 1800, greater than or equal to about 1900, greater than or equal to about 2000, greater than or equal to about 2100, greater than or equal to about 2200, greater than or equal to about 2300, greater than or equal to about 2400, greater than or equal to about 2500, greater than or equal to about 3000, greater than or equal to about 3500, greater than or equal to about 4000, greater than or equal to about 4500, greater than or equal to about 5000, greater than or equal to about 5500, greater than or equal to about 6000, greater than or equal to about 7000, greater than or equal to about 8000, greater than or equal to about 9000, greater than or equal to about 10,000, greater than or equal to about 15000, greater than or equal to about 20,000, greater than or equal to about 25000, greater than or equal to about 30,000, greater than or equal to about 35,000, greater than or equal to about 40,000, greater than or equal to about 45,000, greater than or equal to about 50,000, greater than or equal to about 55,000, greater than or equal to about 60,000, greater than or equal to about 65,000, greater than or equal to about 70,000, greater than or equal to about 75,000, greater than or equal to about 80,000, greater than or equal to about 85,000, greater than or equal to about 90,000, greater than or equal to about 95,000, greater than or equal to about 100,000, greater than or equal to about 120,000, greater than or equal to about 140,000, greater than or equal to about 160,000, greater than or equal to about 180,000, greater than or equal to about 200,000, greater than or equal to about 220,000, greater than or equal to about 240,000, greater than or equal to about 260,000, greater than or equal to about 280,000, greater than or equal to about 300,000, greater than or equal to about 350,000, greater than or equal to about 400,000, greater than or equal to about 450,000, greater than or equal to about 500,000, or greater than or equal to about 550,000. The average (e.g., weight average or number average) molecular weight of the polymer may be less than or equal to about 8,000,000, less than or equal to about 7,000,000, less than or equal to about 6,000,000, less than or equal to about 5,000,000, less than or equal to about 4,000,000, less than or equal to about 3,000,000, less than or equal to about 2,000,000, less than or equal to about 1500,000, less than or equal to about 1200,000, less than or equal to about 1,000,000, less than or equal to about 900,000, less than or equal to about 800,000, less than or equal to about 700,000, less than or equal to about 600,000, less than or equal to about 500,000, less than or equal to about 450,000, less than or equal to about 200,000, less than or equal to about 150,000, less than or equal to about 100,000, less than or equal to about 90,000, less than or equal to about 80,000, less than or equal to about 70,000, less than or equal to about 50,000, less than or equal to about 30,000, less than or equal to about 23,000, or less than or equal to about 20,000.

The molecular weight of the polymer may be obtained taking into consideration a molecular weight (e.g., g/mol) and the degree of polymerization of a monomer or a repeat unit derived therefrom and may exhibit a molecular weight distribution. An average molecular weight of the polymer may be a number average molecular weight, a weight average molecular weight, or a viscosity average molecular weight.

In an embodiment, the average molecular weight of the polymer may be measured by using a solution of the polymer. In order to reduce interactions between molecules of the polymer, the molecular weight may be measured by a dilute solution. The concentration of the polymer solution may be appropriately selected, and may be measured using, for example, a solution in which 1 gram or less of a polymer is dissolved per 100 mL. The average molecular weight of the polymer may be measured by an appropriate method, such as a gel permeation chromatography, an end group analysis, an osmotic pressure method, a capillary viscosity method, or the like.

In a gel permeation chromatography method, a polymer dissolved in a solvent may be separated in accordance with its size and an obtained result can be calibrated using a standard material with a determined molecular weight. In the terminal group analysis method, the molecular weight may be measured by quantifying a functional group (e.g., a carboxyl group) by dissolving a polymer in a solvent. Each measurement method may easily and reproducibly provide substantially the same information on molecular weight using commercially available devices according to established standards. The number average molecular weight, the weight average molecular weight, and the viscosity average molecular weight of the polymer may be related to each other.

The polymer may be commercially available from various manufacturers. The manufacturer provides information about the polymer (e.g., a number average molecular weight, a weight average molecular weight, or the like), and thus the polymer having a desired level and type of a molecular weight value may be commercially obtained.

In an embodiment, the polymer or the organic layer may have a relatively high level of solubility in water or an organic solvent (e.g., alcohol, DMSO, etc.) that may be mixed with water, and the viscosity of the solution for coating may be adjusted relatively freely when the organic layer is manufactured. Therefore, compared to an adhesive composition (e.g., a curable resin-based composition) having a high viscosity, a high degree of freedom may be provided when forming a film.

The organic layer or the polymer may further include or may not include an additive. The additive may include an inorganic acid such as a hydrochloric acid, a phosphoric acid, a carbonic acid, or a sulfuric acid; a C2-50 carboxylic acid compound (e.g., represented by R(COOH)ₙ), a sulfinic acid compound (e.g., represented by R(SO₂H)ₙ), a sulfonic acid compound (e.g., represented by R(SO₃H)ₙ), or a combination thereof. In the formulae above, the R may be a substituted or unsubstituted C1 to C50 aliphatic or aromatic hydrocarbon group, for example, a substituted or unsubstituted alkyl group, a substituted or unsubstituted alkenyl group, a substituted or unsubstituted alkynyl group, or a substituted or unsubstituted aryl group, and the n is an integer of 1 to 10, 2 to 8, or 3 to 6. The carboxylic acid compound, the sulfinic acid compound, the sulfonic acid compound, or a combination thereof may further include a hydroxy group.

The additive may include a polycarboxylic acid compound having two or more carboxylic acid groups. The polycarboxylic acid compound may be non-polymeric compound. The polycarboxylic acid compound may be a compound having 2 to 10 carboxylic acid groups. The polycarboxylic acid compound may have 1 to 10, 2 to 5, or 3 to 4 C1-C100, C2-C60, or C6-C15 aliphatic hydrocarbon group(s), 1 to 10, 2 to 5, 3 to 4 C6-C50 or C6-C15 aromatic hydrocarbon group(s), or a combination thereof. The polycarboxylic acid compound may further include a hydroxy group.

The polycarboxylic acid compound may include a compound represented by HOOC-A-(COOH)ₘ, wherein A is a single bond, a carbon atom, a substituted or unsubstituted C1 to C100 (C1-C50, C5-C15, C6-C12) aliphatic hydrocarbon group, such as alkylene, alkenylene, or alkynylene, a substituted or unsubstituted C6 to C40 aromatic hydrocarbon group, or a combination thereof, m is greater than or equal to about 1, greater than or equal to about 2, greater than or equal to about 3, or greater than or equal to about 4, and less than or equal to about 10, less than or equal to about 8, less than or equal to about 6, less than or equal to about 3. In the group A, at least one methylene may be replaced with C(O), NH, O, C(O)O, C(O)NH, or a combination thereof. The polycarboxylic acid compound may have a carbon number of greater than or equal to about 2, greater than or equal to about 3, greater than or equal to about 4, greater than or equal to about 5, greater than or equal to about 6, greater than or equal to about 7, or greater than or equal to about 8. The polycarboxylic acid compound may have a carbon number of less than or equal to about 100, less than or equal to about 60, less than or equal to about 15, less than or equal to about 14, less than or equal to about 13, less than or equal to about 12, less than or equal to about 11, less than or equal to about 10, less than or equal to about 9, less than or equal to about 8, less than or equal to about 7, less than or equal to about 6, or less than or equal to about 5.

The additive may include benzoic acid, succinic acid, maleic acid, fumaric acid, malic acid, glutaric acid, adipic acid, pimelic acid, citric acid, oxalic acid, malonic acid, phthalic acid, isophthalic acid, terephthalic acid, trimellitic acid, hemimellitic acid, azelaic acid, suberic acid, tartaric acid, itaconic acid, dodecanedioic acid, sulfuric acid, acetic acid, (meth)acrylic acid, or a combination thereof.

In the organic layer or the polymer material, an amount of a crosslinked polymer (e.g., crosslinked poly(meth)acrylate, crosslinked epoxy, crosslinked polysiloxane, crosslinked urethane polymer, a crosslinked thiolene polymer, etc.) may be less than or equal to about 5 wt %, less than or equal to about 3 wt %, less than or equal to about 1 wt %, less than or equal to about 0.9 wt %, less than or equal to about 0.8 wt %, less than or equal to about 0.7 wt %, less than or equal to about 0.6 wt %, less than or equal to about 0.5 wt %, less than or equal to about 0.4 wt %, less than or equal to about 0.3 wt %, less than or equal to about 0.2 wt %, or less than or equal to about 0.1 wt %, based on a total weight of the organic layer. The organic layer may not substantially include a crosslinked polymer.

The organic layer or the polymer may be configured to dissolve at least a portion thereof if immersed in water (or a C1 to C5 alcohol). The temperature of the water (or the temperature of the C1 to C5 alcohol) may be greater than or equal to about 20° C., greater than or equal to about 25° C., or greater than or equal to about 30° C. The temperature of the water (or the temperature of the C1 to C5 alcohol) may be less than or equal to a boiling point thereof (for example, about 50° C. or less, or about 30° C. or less).

In an embodiment, a thickness of the organic layer or the polymer may be greater than or equal to about 10 nm, greater than or equal to about 30 nm, greater than or equal to about 50 nm, greater than or equal to about 70 nm, greater than or equal to about 90 nm, greater than or equal to about 100 nm, greater than or equal to about 120 nm, greater than or equal to about 140 nm, greater than or equal to about 160 nm, greater than or equal to about 180 nm, greater than or equal to about 200 nm, greater than or equal to about 250 nm, greater than or equal to about 300 nm, greater than or equal to about 350 nm, greater than or equal to about 400 nm, greater than or equal to about 450 nm, greater than or equal to about 500 nm, greater than or equal to about 550 nm, greater than or equal to about 600 nm, greater than or equal to about 650 nm, greater than or equal to about 700 nm, greater than or equal to about 750 nm, greater than or equal to about 800 nm, greater than or equal to about 850 nm, greater than or equal to about 900 nm, greater than or equal to about 950 nm, greater than or equal to about 1 micrometer (μm), or greater than or equal to about 1.5 μm.

The thickness of the organic layer may be less than or equal to about 1 centimeter, for example, less than or equal to about 50 millimeters (mm), less than or equal to about 10 mm, less than or equal to about 1 mm, less than or equal to about 0.5 mm, less than or equal to about 0.15 mm, less than or equal to about 100 μm, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, or less than or equal to about 1 μm. The thickness of the organic layer can be greater than or equal to about 10 nm, greater than or equal to about 100 nm, greater than or equal to about 500 nm, greater than or equal to about 1 μm, or greater than or equal to about 1.5 μm.

The electroluminescent device of an embodiment may further include a container configured to accommodate at least a portion of a stacked structure including a first electrode, a light emitting layer, an electron transport layer, and a conductor thin film (or a second electrode). The container may include a light transmitting member. An additional member (e.g., a light transmitting or non-transmissive material, a seal material) connected to the light transmitting member may be further included. In an embodiment, the container may be an integrated material or structure. In an embodiment, the container may be formed by combining a plurality of members. In an embodiment, the container may be an integrated light transmitting member (e.g., element or material, see FIG. 2B and FIG. 8 encap glass). In an embodiment, the container may include a light transmitting member and a seal. The container may be an encapsulation element for the stacked structure.

The container or the light transmitting member may include an organic material such as a polymer, an inorganic material such as glass, an organic/inorganic hybrid material, or a combination thereof. The container may be an oven or a chamber. Details of the container (e.g., material, transmittance, etc.) may refer to the details for the substrate described herein. In an embodiment, the oven may be an equipment or an apparatus configured to expose a given material to a high temperature environment (e.g., a post treatment temperature described herein such as a temperature of 50° C. or higher, 70° C. or higher, 90° C. or higher), and the heating manner is not particularly limited. The oven includes a hollow chamber, and includes a heating element configured to heat the chamber in a controlled manner. The hollow chamber may provide the defined space.

In the electroluminescent device of an embodiment, the organic layer may be disposed to be adjacent to or in contact with the container or the light-transmitting member. The organic layer may be applied or coated on a surface of the container or the light-transmitting member. In the electroluminescent device of an embodiment, the container including the organic layer may be replaced with a new container after post-treatment, and thus, the electroluminescent device of an embodiment may not include the organic layer.

In an embodiment, the electroluminescent device may further include a hole auxiliary layer 2, 20 between the first electrode 1, 10 and the light emitting layer 3, 30. The hole auxiliary layer 2, 20 may include a hole injection layer, a hole transport layer, an electron blocking layer, or a combination thereof. The hole auxiliary layer 2, 20 may be a single layer or a multilayer structure in which adjacent layers include different components. (See, FIGS. 1A, 1B, 2A, and 2B)

The hole auxiliary layer 2, 20 may have a HOMO energy level that can be matched with the HOMO energy level of the light emitting layer 3, 30 in order to enhance mobility of holes transferred from the hole auxiliary layer 2, 20 to the light emitting layer 3, 30. In an embodiment, the hole auxiliary layer 2, 20 may include a hole injection layer close to, e.g., adjacent, the first electrode 1, 10 and a hole transport layer close to, e.g., adjacent, the light emitting layer 3, 30.

In an embodiment, the material included in the hole auxiliary layer 2, 20 (e.g., a hole transport layer, a hole injection layer, or an electron blocking layer) is not particularly limited, and may include, for example, poly(9,9-dioctyl-fluorene-co-N-(4-butylphenyl)-diphenylamine) (TFB), polyarylamine, poly(N-vinylcarbazole), poly(3,4-ethylenedioxythiophene) (PEDOT), poly(3,4-ethylenedioxythiophene): polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenyl]cyclohexane (TAPC), a p-type metal oxide (e.g., NiO, WO₃, MoO₃, etc.), a carbon-based material such as graphene oxide, or a combination thereof, but is not limited thereto.

In the hole auxiliary layer, the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

A device according to an embodiment as shown in FIG. 3A may have a normal structure. In the device of an embodiment, the anode 10 disposed on the transparent substrate 100 may include a metal oxide-based transparent electrode (e.g., an ITO electrode), and the cathode 50 facing the anode 10 may include a conductive metal (e.g., having a relatively low work function, Mg, Al, etc.). The hole auxiliary layer 20 (e.g., a hole injection layer such as PEDOT:PSS, p-type metal oxide, or a combination thereof; a hole transport layer such as TFB, polyvinylcarbazole (PVK), or a combination thereof; or a combination thereof) may be provided between the transparent electrode 10 and the light emitting layer 30. The hole injection layer may be disposed close to, e.g., adjacent, the transparent electrode and the hole transport layer may be disposed close to, e.g., adjacent, the light emitting layer. The electron transport layer or the electron auxiliary layer including the same (such as an electron injection/transport layer) 40 may be disposed between the light emitting layer 30 and the cathode 50. (See: FIG. 3A, FIG. 3B, FIG. 3C, FIG. 5A, FIG. 8)

In an embodiment, the electroluminescent device of an embodiment may be manufactured by a method, which includes:
forming a light emitting (e.g., a patterned) layer including a semiconductor nanoparticle on or over a first electrode, forming an electron transport layer on the light emitting layer, and forming a second electrode or a thin film conductor on or over the electron transport layer to obtain a stacked structure. The method further comprises forming an organic layer on or over the electron transport layer and conducting a post-treatment for the stacked structure.

In an embodiment, the method may further include forming a hole auxiliary layer on the first electrode (for example, disposed on a substrate), for example via a physical deposition (e.g., a vapor deposition) or a coating process. The method may further include forming an electron injection layer and/or a hole blocking layer on or over the electron transport layer. The forming of the light emitting layer (or a patterned layer) of the semiconductor nanoparticles is the same as described herein.

The post-treatment may be conducted with using an organic layer or a polymer described herein and optionally a container. In an embodiment, the post-treatment may include
positioning at least a portion of the stacked structure (e.g., the electron transport layer and the thin film conductor) with the organic layer or the polymer in a first space; and
maintaining (or heating) the first space at a post-treatment temperature of greater than or equal to about 40° C.

The post-treatment temperature may be less than or equal to about 200° C., less than or equal to about 180° C., less than or equal to about 160° C., less than or equal to about 150° C., less than or equal to about 140° C., or less than or equal to about 120° C.

The method may further include providing a container to the stacked structure. The container may be configured to define at least a portion of the first space. Details regarding the container are the same as described herein.

The space may be a closed space, for example, a sealed space or a hermitic or airtight space. The method may include removing the container or separating the stacked structure from the container after the post-treatment. The post-treatment may be performed for a predetermined time.

The container may include a light-transmitting member (for example, a light transmitting material or component). The container may be or include an encapsulation glass configured to accommodate at least a portion (or the entire) of the stacked structure. The container may be a separate device or a separate apparatus that can control a temperature, such as an oven or a chamber, and provide a space (e.g., a closed space).

Details of the organic layer and the post treatment are the same as described herein.

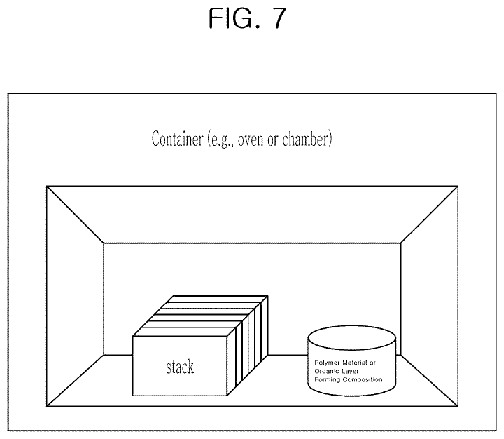

In the method of an embodiment, a stacked structure may be obtained by forming a light emitting layer and an electron transport layer on a first electrode, and for example, between the pixel defining layers (PDL), and then forming a thin film conductor on the electron transport layer (see FIGS. 5A and 5B). The method may further include forming a hole auxiliary layer on the first electrode, for example, prior to the formation of the light emitting layer. The organic layer (or the polymer material) and the container are provided to the stacked structure thus obtained so that the organic layer (or the polymer material) and at least a portion of the stacked structure (for example, the electron transporting layer and the thin film conductor) can be positioned in the space defined by the container. (see FIG. 5A, FIG. 6A, and FIG. 8). In an embodiment, the container may be an oven or a chamber (see FIG. 7)

Surprisingly, the present inventors have found that the properties of the light-emitting device can be significantly improved by keeping the organic layer (or the polymer material) and the stacked structure in the first space at the predetermined post treatment temperature, for example, for a predetermined time. Without wishing to be bound by any theory, it is believed that the organic layer or the polymer material can provide moisture and optionally an acid, e.g., H⁺, under a post treatment condition described herein. The released moisture and optionally the released acid may diffuse through the thin film conductor to modify a surface of the metal oxide particle in the electron transport layer thereby improving the properties of the light-emitting device.

In an embodiment, the thin film conductor or the second electrode may have a prescribed thickness and have a conductivity capable of serving as an electron injection conductor and may allow the moisture and optionally acid released from the organic layer or the polymer material to be diffused or spread (for example downward) and to be transferred to the electron transport layer disposed under the thin film conductor. By providing a moisture vapor (and optionally an acid) environment, and providing a relatively high-temperature environment, can promote the surface modification reaction described.

The method may further include preparing an organic layer-forming composition including the polymer and a liquid vehicle. The organic layer forming composition may or may not further include the additive. Details of the polymer and the additive are the same as described herein. The concentration of the polymer and the additive may be appropriately selected in consideration of the type of the compound and the thickness of the organic layer to be formed.

The method may include applying the organic layer forming composition on the electron transport layer (and, optionally, the second electrode). The method may include applying the organic layer forming composition on (e.g., onto) a surface of the container so that the container faces the electron transport layer or the second electrode. In the method of an embodiment, the organic layer forming composition may be applied to the electron transport layer (and the second electrode) or a surface of the container to form an organic layer. The method may include removing (e.g., evaporating) at least a portion of the liquid vehicle from the applied composition for forming the organic layer.

The liquid vehicle above may include water; a C1-10 alcohol such as ethanol, methanol, propanol, isopropanol, (iso)propanol, (iso)butanol, (iso)pentanol, hexanol, heptanol, octanol, nonanol, etc.; a nitrile solvent such as acetonitrile, etc.; a sulfoxide solvent such as dimethyl sulfoxide, diethyl sulfoxide, ethylmethyl sulfoxide; an ester solvent such as ethyl acetate, or a combination thereof. The liquid vehicle may include a mixture of water and a C1-10 alcohol. The liquid vehicle may include or may be water.

The polymer may be dissolved well in a water or an organic solvent (e.g., an alcohol), for example, having a desired level of solubility in water or an organic solvent, to relatively readily form an (transparent) organic layer-forming composition with an appropriate viscosity. The viscosity of the organic layer-forming composition at room temperature (e.g., about 20-30° C. or about 25° C.) may range from about 2 centipoise (cPs) to about 2000 cPs, about 3 cPs to about 1500 cPs, about 7 cPs to about 1200 cPs, about 10 cPs to about 1000 cPs, about 15 cPs to about 800 cPs, about 20 cPs to about 700 cPs, about 30 cPs to about 500 cPs, about 40 cPs to about 150 cPs, about 50 cPs to about 100 cPs, or a combination thereof, but is not limited thereto.

In the organic layer-forming composition, a concentration of the polymer can be appropriately selected in consideration of a type of polymer, a desired thickness of the organic layer, and the like. In an embodiment, the concentration of the polymer in the organic layer-forming composition may be, respectively, greater than or equal to about 0.01 wt %, greater than or equal to about 0.05 wt %, greater than or equal to about 0.1 wt %, greater than or equal to about 0.5 wt %, greater than or equal to about 1 wt %, greater than or equal to about 2 wt %, greater than or equal to about 3 wt %, greater than or equal to about 3.3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 11 wt %, greater than or equal to about 12 wt %, greater than or equal to about 13 wt %, greater than or equal to about 14 wt %, greater than or equal to about 15 wt %, greater than or equal to about 16 wt %, greater than or equal to about 17 wt %, greater than or equal to about 18 wt %, greater than or equal to about 19 wt %, greater than or equal to about 20 wt %, greater than or equal to about 21 wt %, greater than or equal to about 22 wt %, greater than or equal to about 23 wt %, greater than or equal to about 24 wt %, greater than or equal to about 25 wt %, greater than or equal to about 26 wt %, greater than or equal to about 27 wt %, greater than or equal to about 28 wt %, greater than or equal to about 29 wt %, greater than or equal to about 30 wt %, greater than or equal to about 31 wt %, greater than or equal to about 32 wt %, greater than or equal to about 33 wt %, greater than or equal to about 34 wt %, greater than or equal to about 35 wt %, greater than or equal to about 36 wt %, greater than or equal to about 37 wt %, greater than or equal to about 38 wt %, greater than or equal to about 39 wt %, or greater than or equal to about 40 wt %, based on a total weight of the composition. The concentration of the polymer in the organic layer-forming composition may be, respectively, less than or equal to about 99 wt %, less than or equal to about 90 wt %, less than or equal to about 85 wt %, less than or equal to about 80 wt %, less than or equal to about 75 wt %, less than or equal to about 70 wt %, less than or equal to about 65 wt %, less than or equal to about 60 wt %, less than or equal to about 55 wt %, less than or equal to about 50 wt %, less than or equal to about 45 wt %, less than or equal to about 40 wt %, less than or equal to about 35 wt %, less than or equal to about 30 wt %, less than or equal to about 25 wt %, less than or equal to about 20 wt %, less than or equal to about 15 wt %, less than or equal to about 10 wt %, or less than or equal to about 5 wt %, based on a total weight of the composition.

In an embodiment, the organic layer forming composition may further include the additive, and a concentration of the additive in the organic layer-forming composition may be in a range of from about 0.0001 mole/L (M) to about 10M, about 0.0005M to about 5M, about 0.001 M to about 4M, about 0.005M to about 3M, about 0.01 M to about 2M, about 0.05M to about 1.5M, about 0.1 M to about 1.3M, about 0.1 M to about 1.2M, about 0.15M to about 1 M, about 0.15M to about 0.9M, about 0.2M to about 0.8M, about 0.3M to about 0.7M, about 0.4M to about 0.6M, about 0.45M to about 0.55M, or a combination thereof.

The organic layer forming composition may exhibit a pH of greater than or equal to about 1, greater than or equal to about 1.5, greater than or equal to about 2, greater than or equal to about 3, greater than or equal to about 3.5, greater than or equal to about 4, greater than or equal to about 4.5, greater than or equal to about 5, or greater than or equal to about 5.5, and less than or equal to about 8.5, less than or equal to about 8, less than or equal to about 7.5, less than or equal to about 7, less than or equal to about 6.5, less than or equal to about 6, less than or equal to about 5.5, less than or equal to about 5.2, less than or equal to about 5, or less than or equal to about 4.8, or less than or equal to about 4. The concentration of the organic layer-forming composition at these pH levels may be the same as described herein.

The method of applying the organic layer forming composition is not particularly limited and may be appropriately selected. The application may involve a spin coating, a dropwise coating, or a combination thereof. After the application of the organic layer forming composition, an excess amount of the composition may be removed by spinning or the like.

The formation of the organic layer may not involve a polymerization and/or a crosslinking reaction. Accordingly, an amount of a crosslinked polymer in the organic layer may be less than 1% by weight, based on a total weight of the organic layer or the polymer. Without wishing to be bound by a particular theory, it is believed that the provision of a layer containing a crosslinked polymer (for example, as a major component) on or over the electron transport layer may result in an undesired and significant light absorption within a range of wavelengths of interest. In other words, a crosslinked polymer (organic layer) may make it difficult, or at least less efficient to extract light from the device, for example, for a front light-emitting type display panel having a second electrode as a transparent electrode.

In addition, the present inventors have found that the organic layer forming composition including a crosslinked resin may cause a significant increase in viscosity, and thus forming an organic layer with a desired or controlled thickness may become more difficult. The present inventors have found that the organic layer comprising a crosslinked resin as a main component does not sufficiently provide a moisture and optionally acid component to achieve the objective of the method described herein.

In an embodiment, the post-treatment may be performed under an appropriate atmosphere (e.g., under an inert gas atmosphere, in an oxygen-free atmosphere, or in air).

In the organic layer of an embodiment, the polymer material for example, having a molecular weight described herein may exhibit hydrophilicity, and thus, a limited amount of moisture optionally together with relatively labile acid moieties (e.g., C(O)OH groups) may exist in the organic layer or in the polymer material. In an embodiment, the organic layer or the polymer material may readily and gradually over time release the moisture and optionally the acid component under a predetermined atmosphere (e.g., an inert gas atmosphere or an ambient atmosphere), and at a post treatment temperature described herein. The released moisture, and optionally the released acid component, may diffuse (e.g., through a thin film conductor of a predetermined thickness) to reach a metal oxide nanoparticle present in the electron auxiliary layer, facilitating a surface modification of the nanoparticle. For example, the moisture, and optionally the acid component, may gradually move to the electron auxiliary layer and can interact or react (e.g., participating a dehydration condensation reaction) with the metal oxide nanoparticle (e.g., with a hydroxy group or a defect site that may be present on a surface of the metal oxide nanoparticle). It is believed that the interaction and the reaction may modify the surface of the metal oxide nanoparticle, possibly eliminating a defect and/or leading to a growth of the metal oxide nanoparticle.

The post-treatment temperature may be greater than or equal to about 40° C., greater than or equal to about 45° C., greater than or equal to about 50° C., greater than or equal to about 55° C., greater than or equal to about 60° C., greater than or equal to about 65° C., greater than or equal to about 70° C., or greater than or equal to about 75° C. The post-treatment temperature may be less than or equal to about 200° C., less than or equal to about 190° C., less than or equal to about 180° C., less than or equal to about 160° C., less than or equal to about 150° C., less than or equal to about 140° C., less than or equal to about 120° C., less than or equal to about 100° C., less than or equal to about 90° C., less than or equal to about 80° C., or less than or equal to about 70° C.

The post-treatment time may be greater than or equal to about 30 minutes, greater than or equal to about 1 hour, greater than or equal to about 2 hours, greater than or equal to about 3 hours, greater than or equal to about 5 hours, greater than or equal to about 7 hours, greater than or equal to about 12 hours, greater than or equal to about 20 hours, greater than or equal to about 24 hours, greater than or equal to about 36 hours, greater than or equal to about 48 hours, or greater than or equal to about 50 hours. The post-treatment time may be less than or equal to about 30 days, less than or equal to about 20 days, less than or equal to about 10 days, less than or equal to about 5 days, less than or equal to about 3 days, less than or equal to about 70 hours, less than or equal to about 50 hours, less than or equal to about 2 days, less than or equal to about 30 hours, less than or equal to about 1 day, less than or equal to about 18 hours, less than or equal to about 14 hours, less than or equal to about 8 hours, less than or equal to about 7 hours, less than or equal to about 6 hours, less than or equal to about 5 hours, less than or equal to about 4 hours, less than or equal to about 3 hours, less than or equal to about 2 hours, or less than or equal to about 1 hour.

The method of an embodiment may further include removing the container after the post-treatment and providing a conductive layer on the thin film conductor to increase a thickness of the thin film conductor or the second electrode. After the thin film conductor or the second electrode acquires the increased thickness as desired, a new container may be used (e.g., placed). (See FIG. 6A and FIG. 6B).

In an embodiment, a light emitting device or an electroluminescent device (hereinafter, “light emitting device) includes a first electrode (e.g., a hole injection conductor or an anode) and a second electrode, a light emitting layer disposed between the first electrode and the second electrode; and an electron transport layer between the light emitting layer and the second electrode, and the light emitting layer includes a semiconductor nanoparticle, and the light emitting layer is configured to emit a first light.

The electron transport layer includes a metal oxide nanoparticle, and the metal oxide nanoparticle has a size of greater than or equal to about 1 nm and less than or equal to about 30 nm. The metal oxide nanoparticle includes zinc, and optionally a Group IIA metal, Zr, W, Li, Ti, Y, Al, gallium, indium, tin (Sn), cobalt (Co), vanadium (V), or a combination thereof.

The second electrode have a thickness of greater than or equal to about 1 nm (or greater than or equal to about 11 nm) and less than or equal to about 50 nm, and the second electrode has a light transmittance for the first light that is greater than or equal to about 50% and less than or equal to about 100%, and the first electrode is configured to reflect at least a portion of the first light.

The first electrode may include a hole injection conductor, and the second electrode may include an electron injection conductor.

The semiconductor nanoparticle or the light emitting layer may not contain cadmium, lead, mercury, or a combination thereof.

The second electrode may have a thickness of greater than or equal to about 15 nm and less than or equal to about 40 nm.

The first electrode may be configured to reflect at least a portion of the first light.

The light-emitting device may be configured to emit green light when a voltage is applied. The light-emitting device may be configured to emit blue light when a voltage is applied. The light-emitting device may be configured to emit red light when a voltage is applied.

The light emitting device may further include an organic layer or a polymer, for example, disposed on the electron transport layer. The organic layer and the polymer are the same as described herein.

The organic layer or the polymer material may be disposed to be spaced apart from the electron transport layer and the second electrode. The organic layer may be disposed to face the electron transport layer and the second electrode or conductor thin film.

The electron transport layer may have a first surface facing the emission layer and a second surface facing the first surface, and the organic layer or the polymer material may be disposed on the second surface. The organic layer or the polymer material may be disposed to be spaced apart from the electron transport layer (e.g., separated from the electron transport layer).

The organic layer or the polymer material may have a thickness of greater than or equal to about 10 nm, or greater than or equal to about 100 nm. The thickness of the organic layer or the polymer material may be less than or equal to about 100 micrometers (μm), or less than or equal to about 10 μm.

The thin film conductor or the second electrode may have a first surface facing a surface of the electron auxiliary layer and a second surface opposite to the first surface, and the organic layer or the polymer material may be disposed, spacing apart from the electron transport layer and/or the second electrode and may be disposed to face at least a portion (e.g., all) of the surface of the electron transport layer and/or at least a portion (e.g., all) of the second surface of the second electrode.

Details for the light emitting device (e.g., the elements thereof such as the semiconductor nanoparticle, the metal oxide nanoparticle, the first/second electrode, the thin film conductor, the organic layer or the polymer) are the same as described herein. For the details of the second electrode, it is possible to refer to the description of the conductor thin film, as well.

The light emitting device of an embodiment may be configured to emit red light, green light, or blue light. Details (e.g., the wavelength) of red light, green light, or blue light are the same as described herein.

In an embodiment, the light emitting (or electroluminescent) device may have a maximum external quantum efficiency (EQE) of greater than or equal to about 1%, greater than or equal to about 2%, greater than or equal to about 3%, greater than or equal to about 4%, greater than or equal to about 5%, greater than or equal to about 5.5%, greater than or equal to about 6%, greater than or equal to about 6.5%, greater than or equal to about 7%, greater than or equal to about 7.5%, greater than or equal to about 7.7%, greater than or equal to about 8%, greater than or equal to about 8.5%, greater than or equal to about 9%, greater than or equal to about 9.5%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The maximum external quantum efficiency (EQE) may be less than or equal to about 60%, less than or equal to about 50%, less than or equal to about 40%, less than or equal to about 30%, or less than or equal to about 20%.

The light emitting (or electroluminescent) device of an embodiment may exhibit a maximum luminance of greater than or equal to about 10,000 candela per square meter (cd/m²), greater than or equal to about 30,000 cd/m², greater than or equal to about 40,000 cd/m², greater than or equal to about 60,000 cd/m², greater than or equal to about 65,000 cd/m², greater than or equal to about 70,000 cd/m², greater than or equal to about 80,000 cd/m², greater than or equal to about 90,000 cd/m², greater than or equal to about 100,000 cd/m², greater than or equal to about 110,000 cd/m², or greater than or equal to about 120,000 cd/m².

The light emitting (or electroluminescent) device of an embodiment may exhibit a maximum luminous efficiency of greater than or equal to about 5 candela per ampere (cd/A), greater than or equal to about 5.5 cd/A, greater than or equal to about 6 cd/A, greater than or equal to about 7 cd/A, greater than or equal to about 8 cd/A, greater than or equal to about 9 cd/A, greater than or equal to about 10 cd/A, greater than or equal to about 15 cd/A, greater than or equal to about 20 cd/A, or greater than or equal to about 30 cd/A.

In an embodiment, as measured by driving the device at a predetermined initial luminance (for example, about 650 nit or about 146 nit), the light emitting (or electroluminescent) device may exhibit a T50 of greater than or equal to about 10 hours, greater than or equal to about 20 hours, greater than or equal to about 25 hours, greater than or equal to about 30 hours, greater than or equal to about 40 hours, greater than or equal to about 50 hours, greater than or equal to about 60 hours, greater than or equal to about 65 hours, greater than or equal to about 70 hours, greater than or equal to about 80 hours, greater than or equal to about 90 hours, greater than or equal to about 100 hours, greater than or equal to about 120 hours, greater than or equal to about 150 hours, greater than or equal to about 180 hours, greater than or equal to about 200 hours, or greater than or equal to about 250 hours.

In an embodiment, as measured by driving the device at a predetermined initial luminance (for example, about 650 nit or about 146 nit), the light emitting device may have a T90 of greater than or equal to about 5 hours, e.g., a T90 of greater than or equal to about 6 hours, greater than or equal to about 7 hours, greater than or equal to about 7.5 hours, greater than or equal to about 8 hours, greater than or equal to about 9 hours, greater than or equal to about 10 hours, greater than or equal to about 20 hours, greater than or equal to about 30 hours, greater than or equal to about 40 hours, greater than or equal to about 50 hours, greater than or equal to about 60 hours, greater than or equal to about 70 hours, greater than or equal to about 80 hours, greater than or equal to about 90 hours, greater than or equal to about 100 hours, greater than or equal to about 110 hours, greater than or equal to about 120 hours, or greater than or equal to about 130 hours. The T90 may be from about 35 hours to about 1500 hours, from about 55 hours to about 1200 hours, from about 85 hours to about 1000 hours, from about 105 hours to about 900 hours, from about 115 hours to about 800 hours, from about 145 hours to about 500 hours, or a combination thereof.

The light emitting (or electroluminescent) device may exhibit an increased stability. After being heat-treated at about 70° C. for about 2 days in air or an inert atmosphere and being driven at about 146 nits, the light emitting (or electroluminescent) device of an embodiment may exhibit a voltage increase that is less than or equal to about 30% or less than or equal to about 25% of an initial voltage without the heat treatment.

In an embodiment, a display device includes the light emitting (e.g., electroluminescent) device described herein.

The display device (e.g., a display panel) may include a first pixel and a second pixel that is configured to emit light different from the light of the first pixel.

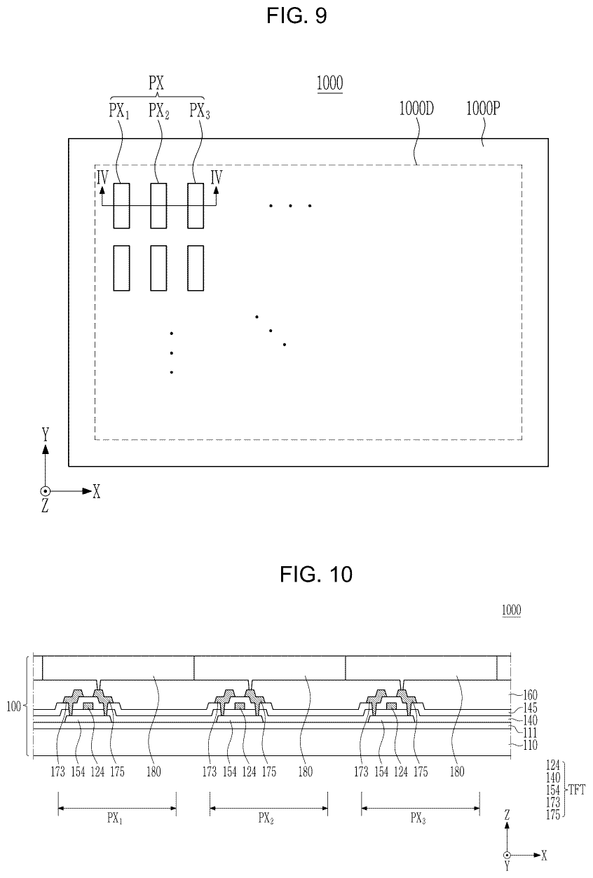

Referring to FIG. 9, a display panel 1000 according to an embodiment includes a display area 1000D for displaying an image and a non-display area 1000P disposed around the display area 1000D, in which the binding element may be located.

The display area 1000D may include a plurality of pixels PXs arranged along a row (e.g., x direction) and/or a column (e.g., y direction), and each pixel PX may include a plurality of sub-pixels PX₁, PX₂, and PX₃ displaying different colors. As an example, a configuration in which three sub-pixels PX₁, PX₂, and PX₃ constitute one pixel PX is illustrated, but the configuration is not limited thereto. An additional sub-pixel such as a white sub-pixel may be further included, and one or more sub-pixel displaying the same color may be included. The plurality of pixels PXs may be arranged in, for example, a Bayer matrix, a PenTile matrix, and/or a diamond matrix, but is not limited thereto.

Each of the sub-pixels PX₁, PX₂, and PX₃ may be configured to display a color of three primary colors or a combination of three primary colors, for example, red, green, blue, or a combination thereof (e.g., white light). For example, the first sub-pixel PX₁ may be configured to display red, the second sub-pixel PX₂ may be configured to display green, and the third sub-pixel PX₃ may be configured to display blue.

In the figure, each of the sub-pixels are depicted to have the same size, but the present disclosure is not limited thereto. For example, at least one of the sub-pixels may be larger or smaller, or have a different shape, than another sub-pixel.

In an embodiment, the display panel of an embodiment may include a light emitting panel 100 which may include a lower substrate 110, a buffer layer 111, a thin film transistor TFT, and a light emitting element 180. The display panel may further include a circuit element for switching and/or driving each of the light emitting elements.

Referring to FIG. 10, in the light emitting panel of an embodiment, the light emitting element 180 may be disposed for each sub-pixel PX₁, PX₂, and PX₃. The light emitting element 180 disposed in each sub-pixel PX₁, PX₂, and PX₃ may be independently driven. The subpixel may include a blue subpixel, red subpixel, or a green subpixel. At least one of the light emitting element 180 may be an electroluminescent element according to an embodiment described herein.

Details of the substrate are the same as described herein. The buffer layer 111 may include an organic material, an inorganic material, or an organic-inorganic material. The buffer layer 111 may include, for example, an oxide, a nitride, or an oxynitride, and may include, for example, silicon oxide, silicon nitride, silicon oxynitride, or a combination thereof, but is not limited thereto. The buffer layer 111 may be one layer or two or more layers and may cover a portion of or the entire surface of the lower substrate 110. The buffer layer 111 may be omitted.

The thin film transistor TFT may be a three terminal element for switching and/or driving the light emitting element 180, and one or two or more may be included for each sub-pixel. The thin film transistor TFT may include a gate electrode 124, a semiconductor layer 154 overlapped with the gate electrode 124, a gate insulating layer 140 between the gate electrode 124 and the semiconductor layer 154, and a source electrode 173 and a drain electrode 175 electrically connected to the semiconductor layer 154. A coplanar top gate structure is shown as an example, but the structure is not limited thereto and may have various structures.

The gate electrode 124 is electrically connected to a gate line (not shown), and may include, for example, a low-resistance metal such as aluminum (Al), molybdenum (Mo), copper (Cu), titanium (Ti), silver (Ag), gold (Au), an alloy thereof, or a combination thereof, but is not limited thereto.

The semiconductor layer 154 may be an inorganic semiconductor such as amorphous silicon, polycrystalline silicon, or oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but they are not limited thereto. The semiconductor layer 154 may include a channel region and doped regions disposed on both sides of the channel region and electrically connected to the source electrode 173 and the drain electrode 175, respectively.

The gate insulating layer 140 may include an organic material, an inorganic material, or an organic-inorganic material, and may include, for example, an oxide, a nitride, or an oxynitride, and may include, for example, silicon oxide, silicon nitride, silicon oxynitride, or a combination thereof, but is not limited thereto. In the drawing, an example in which the gate insulating layer 140 is formed on the entire surface of the lower substrate 110 is illustrated, but the present disclosure is not limited thereto and may be selectively formed between the gate electrode 124 and the semiconductor 154. The gate insulating layer 140 may be formed of one or two or more layers.

The source electrode 173 and the drain electrode 175 may include, for example, a low-resistance metal such as aluminum (Al), molybdenum (Mo), copper (Cu), titanium (Ti), silver (Ag), gold (Au), an alloy thereof, or a combination thereof, but are not limited thereto. The source electrode 173 and the drain electrode 175 may be electrically connected to the doped regions of the semiconductor layer 154, respectively. The source electrode 173 is electrically connected to a data line (not shown), and the drain electrode 175 is electrically connected to a light emitting element 180.

An interlayer insulating layer 145 is additionally formed between the gate electrode 124 and the source/drain electrodes 173 and 175. The interlayer insulating layer 145 may include an organic material, an inorganic material, or an organic-inorganic material, for example, oxide, nitride, or oxynitride, for example, silicon oxide, silicon nitride, silicon oxynitride, or a combination thereof, but is not limited thereto. The interlayer insulating layer 145 may be formed of one or two or more layers.

A protective layer 160 is formed on the thin film transistor TFT. The protective layer 160 may be, for example, a passivation layer. The protective layer 160 may include an organic material, an inorganic material, or an organic-inorganic material, for example, polyacrylic, polyimide, polyamide, poly(amide-imide), or a combination thereof, but is not limited thereto. The protective layer 160 may be formed of one or two or three or more layers.

In an embodiment, one of the first electrode 1, 10 and the second electrode 5, 50, may be a pixel electrode linked to the TFT and the other of them may be a common electrode.

In an embodiment, the light emitting device or the display device including the same may be used in a top emission type, a bottom emission type, a dual emission type, or a combination thereof.

In an embodiment, the first electrode 1, 10 may be a light transmitting electrode and the second electrode 5, 50 may be a reflective electrode, and the display panel may be a bottom emission type display panel that emits light toward the first electrode 10 and the substrate 110, if present. In an embodiment, the first electrode 1, 10 may be a reflective electrode and the second electrode 5, 50 may be a light transmitting electrode, and the display panel may be a top emission type display panel that emits light to the opposite side of the first electrode 10 and the substrate 110 if present. In an embodiment, both the first electrode and the second electrode may be translucent electrodes, and the display panel 1000 may be a both side emission type display panel that emits light on the substrate side and on the opposite side of the substrate.

The display device or an electronic apparatus may include (or may be) a television, a virtual reality/augmented reality (VR/AR) device, a handheld terminal, a monitor, a notebook computer, an electronic display board, a camera, or a part for an automatic, e.g., autonomous, vehicle.

Specific examples are described below. However, the examples described below are only for specifically illustrating or explaining the disclosure, and the scope of the disclosure is not limited thereto.

### EXAMPLES

### 1. Electroluminescence Measurement

A current according to an applied voltage is measured with a Keithley 2635B source meter, and a CS2000 spectrometer was used to measure electroluminescent properties (e.g., luminance) of a light-emitting device.

### 2. Life-Span Characteristics

T90 and T50 were measured with an initial luminance of about 146 nit.

### 3. Electron Microscopic Analysis

A transmission electron microscopy analysis was performed using the UTF30 Tecnai electron microscope.

The following preparations were performed under an inert gas atmosphere (e.g., under nitrogen) unless otherwise specified. A precursor content is provided as a molar content, unless otherwise specified.

### Synthesis Example 1

A 2M (moles per liter) Se/trioctylphosphine (TOP) stock solution, 1 M of a S/TOP stock solution, and 0.1 M of a Te/TOP stock solution were prepared by dispersing selenium (Se), sulfur (S), and tellurium (Te) in trioctylphosphine (TOP), respectively. In a reactor containing trioctylamine, 0.125 millimoles (mmol) of zinc acetate was added to the reactor with oleic acid and heated at 120° C. under vacuum. After 1 hour, nitrogen was introduced into the reactor.

The reactor was heated to 300° C., and the Se/TOP stock solution and the Te/TOP stock solution in a Te:Se mole ratio of 1:15 were rapidly added to, e.g., injected into, the reactor. After 40 minutes, the reaction was complete, and the reaction solution was rapidly cooled to room temperature and acetone was added to the reactor. The resulting product mixture was centrifuged and the precipitate was separated and dispersed in toluene to prepare a ZnSeTe core particle dispersion.

1.8 mmol of zinc acetate and oleic acid were added to a flask containing trioctylamine and the prepared mixture was heated at 120° C. under vacuum for 10 minutes. Nitrogen (N₂) was then introduced into the reactor, the reactor was heated to 180° C., and the prepared ZnTeSe core particle dispersion was added quickly to the reactor. The Se/TOP stock solution and the S/TOP stock solution were also added to the reactor, and the reactor temperature was raised to about 280° C. After 2 hours, the reaction was complete, and the reactor was cooled to room temperature and ethanol was added to facilitate precipitation of the semiconductor nanoparticles, which were separated by centrifuge. The prepared semiconductor nanoparticles emitted blue light, and a photoluminescent spectroscopy analysis using Hitachi F-7000 spectrophotometer confirms that the blue light has a maximum emission peak wavelength of about 455 nanometers (nm).

The synthesized semiconductor nanoparticles (optical density 0.25 at 420 nm, 6 milliliters (mL)) were precipitated with ethanol and centrifuged and the separated nanoparticles dispersed in octane or cyclohexyl benzene to prepare a dispersion.

### Synthesis Example 2: Synthesis of ZnMgO Nanoparticles

Zinc acetate dihydrate and magnesium acetate tetrahydrate were added to a reactor including dimethylsulfoxide at a mole ratio according to the chemical formula of interest and heated at 60° C. in an air atmosphere. Subsequently, a solution of tetramethylammonium hydroxide pentahydrate and ethanol was added to the reactor in a dropwise manner at a speed of 3 milliliters per minute (mL/min). After stirring the mixture, the prepared Zn₁₋ₓMgₓO nanoparticles were centrifuged, separated, and dispersed in ethanol to provide an ethanol dispersion of Zn₁₋ₓMgₓO (x=0.15) nanoparticles.

The prepared nanoparticles were analyzed by a transmission electron microscopic analysis, and confirming that the particles have an average particle size of about 3 nm.

### Example 1

The dispersion of zinc magnesium oxide nanoparticles prepared in Synthesis Example 2 is used as an electron transport layer dispersion (hereinafter, ETL dispersion).

Polyvinyl alcohol (average molecular weight: 22,000, manufacturer: Daejung Chemicals, degree of hydrolysis: 86-88%, product name: Polyvinyl alcohol 500) was dissolved in water to prepare an organic layer forming composition (PVA concentration: 3.3 wt %).

A glass substrate deposited with indium tin oxide (ITO) was surface treated with ultraviolet (UV)-ozone for 15 minutes, and then spin-coated with a poly(3,4-ethylenedioxythiophene): polystyrene sulfonate (PEDOT:PSS) solution (H.C. Starks) and heated at 230° C. for 30 minutes under an Air atmosphere to provide a hole injection layer (HIL) having a thickness of 120 nm.

Subsequently, a poly[(9,9-dioctylfluorenyl-2,7-diyl-co(4,4′-(N-4-butylphenyl)diphenylamine]solution (TFB) (Sumitomo) was spin-coated on the hole injection layer and heated at 230° C. for 30 minutes to provide a hole transport layer (HTL) having a thickness of 35 nm.

The cyclohexyl benzene dispersion of the semiconductor nanoparticles prepared in Synthesis Example 1 was spin-coated on the prepared hole transport layer to prepare a light emitting layer having a thickness of 30 nm, which was then heat-treated at a temperature of about 140° C. under an air atmosphere for 30 minutes.

The ETL dispersion was spin-coated onto the heat-treated light emitting layer and was heat-treated at 140° C. to form an electron transport layer with a thickness of about 50 nm.

Magnesium and silver (molar ratio=10:1) were thermally evaporated on the obtained electron transport layer to form the second electrode having a thickness of 20 nm, thereby obtaining a stacked structure (hereinafter, may be referred to as the QD stack).

As shown in FIG. 5A, the prepared organic layer-forming composition was placed in a form of a droplet and then was spin-coated on onto a surface of an open box-shaped container (e.g., encap glass), followed by solvent removal to form an organic layer 60 with a thickness of about 3 μm.

In the sealed space defined by the container (i.e., encap glass), the stacked structure was placed so that the organic layer was spaced apart from and faced to the thin film conductor, as shown in FIG. 5A. The contained stacked structure was heated and maintained at a 100° C. hot plate for 3 hours to obtain the light-emitting device.

Electroluminescent properties of the prepared light emitting device were measured and the results are shown in Table 1.

### Comparative Example 1

A light emitting device was prepared in the same manner as Example 1 except that the organic layer was not formed.

Electroluminescent properties of the prepared light emitting device were measured and the results are shown in Table 1.

### Example 2

A light emitting device was prepared in the same manner as Example 1 except for using an organic layer forming composition (PVA concentration: 3.3 wt %) prepared by dissolving polyvinyl alcohol (average molecular weight: 66,000, manufacturer: Daejung Chemicals, degree of hydrolysis: 88-89%, product name: Polyvinyl alcohol 1500) in water.

Electroluminescent properties of the prepared light emitting device were measured and the results are shown in Table 1.

### Example 3

A light emitting device was prepared in the same manner as Example 1 except for using an organic layer forming composition (PVP concentration: 3.3 wt %) prepared by dissolving Poly(4-vinylphenol) (PVP, average molecular weight: Mw 25,000, manufacturer: Sigma-Aldrich) in water to form the organic layer, instead of the PVA composition.

Electroluminescent properties of the prepared light emitting device were measured and the results are shown in Table 1.

### Example 4

A light emitting device was prepared in the same manner as Example 1 except for using a pHEMA-containing organic layer forming composition (pHEMA concentration: 3.3 wt %)) prepared by dissolving poly(2-hydroxyethyl methacrylate) (pHEMA, average molecular weight: Mw 20,000, manufacturer: Sigma-Aldrich) in ethanol to form an organic layer, instead of the PVA composition.

Electroluminescent properties of the prepared light emitting device were measured and the results are shown in Table 1.

### Example 5

A light emitting device was prepared in the same manner as Example 1 except that malic acid was added at concentration: 0.1 M to the polyvinyl alcohol solution prepared by dissolving a PVA (average molecular weight: 22,000, manufacturer: Daejung Chemicals, product name: Polyvinyl alcohol 500) in water.

Electroluminescent properties of the prepared light emitting device were measured and the results are shown in Table 1.

TABLE 1

| | | Relative | Rel. | |
|---|---|---|---|---|
| | organic | Max | Luminance | Relative |
| | layer composition | EQE (%) | at 5 V(%) | T50 |
| Comp. | Not using | 100% | 100% | 100% |
| Example 1 | | | | |
| Example 1 | PVA 22000 (3.3 wt %) | 138% | 128% | 220% |
| Example 2 | PVA 66000 (3.3 wt %) | 155% | about | 280% |
| Example 3 | PVP(3.3 wt %) | 131% | 217% | 164% |
| Example 4 | pHEMA(3.3 wt %) | 136% | 194% | 188% |
| Example 5 | PVA 22000 | 168% | 286% | 496% |
| | (3.3 wt %) + MA | | | |

MA: malic acid
PVA: polyvinyl alcohol
PVP: poly(4-vinylphenol)
pHEMA: Poly(2-hydroxyethyl methacrylate)
Relative Max EQE (%): Maximum external quantum efficiency of the given device/Maximum external quantum efficiency of Comparative Example 1×100.
Relative luminance (%): luminance of the given device/luminance of Comparative Example 1×100
Relative T50(%): T50 (hour) of the given device/T50 (hour) of Comparative Example 1×100

From the results in Table 1, it was confirmed that the light emitting devices of the Example exhibited similar or significantly higher luminance together with extended lifespan compared to the light-emitting device of Comparative Example 1.

### Experimental Example 1

The light emitting device manufactured in Example 1 was heat-treated on a hot plate at 120° C. for 3 hours. Electroluminescent properties of the device after the heat treatment were measured, and the results are summarized in Table 2.

The light emitting device manufactured in Comparative Example 1 was heat-treated on a hot plate at 120° C. for 3 hours. Electroluminescent properties of the device after the heat treatment were measured, and the results are summarized in Table 2.

TABLE 2

| | Heat | | Rel. | | |
|---|---|---|---|---|---|
| | treatment | | Luminance | Voltage | |
| | hours | | at 5 volts | at 5 mA | |
| Comp. | 0 | hour | 100% | 4.8 | volts |
| Example 1 | | | | | |
| Comp. | 3 | hours | 4% | 7.5 | volts |
| Example 1 | | | | | |
| Example 1 | 0 | hour | 100% | 4 | volts |
| Example 1 | 3 | hours | 129% | 4.2 | volts |

According to the results of Table 2, the electroluminescent device of Example 1 showed an increase in luminance and a smaller increase in voltage (i.e., resistance) at a given current following heat treatment at 120° C. for 3 hours. In contrast, the electroluminescent device of Comparative Example 1 exhibited a significant decrease in luminance and a substantial increase in voltage (i.e., resistance) at a given current following heat treatment at 120° C. for 3 hours.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An electroluminescent device comprising
a first electrode;
a second electrode;
a light emitting layer disposed between the first electrode and the second electrode, wherein the light emitting layer comprises a semiconductor nanoparticle;
an electron transport layer disposed between the light emitting layer and the second electrode; and
an organic layer comprising a polymer that includes a repeat unit with a hydroxy group,
wherein the electron transport layer comprises a metal oxide nanoparticle, and the metal oxide nanoparticle has a size of greater than or equal to about 1 nm and less than or equal to about 50 nm.

2. The electroluminescent device of claim 1, wherein the organic layer is disposed on the electron transport layer and the second electrode.

3. The electroluminescent device of claim 1, wherein the polymer includes a repeat unit represented by Chemical Formula 1: 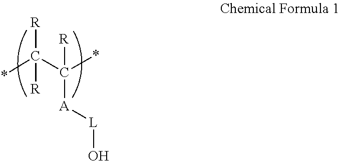
wherein A is a direct bond, —C(O)—, —O—, —C(O)O—, —OC(O)—, —C(O)NH—, —NH—, —S—, —S(O)—, or a combination thereof,
L is a direct bond, a substituted or unsubstituted C1-30 aliphatic hydrocarbon group, a substituted or unsubstituted C6-C20 arylene group,
R are the same or different and each independently hydrogen or a substituted or unsubstituted C1 to C30 alkyl group, and
* is a portion that is bound to an adjacent repeat unit.

4. The electroluminescent device of claim 1, wherein the polymer comprises a first repeat unit represented by Chemical Formula 2, and optionally, a second repeat unit represented by Chemical Formula 3: 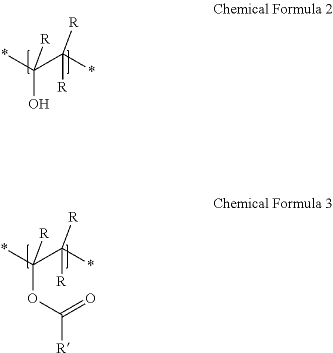
wherein,
* is a portion linked to an adjacent repeat unit,
R are the same or different and each independently hydrogen or a substituted or unsubstituted C1 to C30 alkyl group, and
R′ is a substituted or unsubstituted C1-C10 alkyl group.

5. The electroluminescent device of claim 4, wherein the polymer has a solubility in water of greater than or equal to about 1 g/L and less than or equal to about 1000 g/L.

6. The electroluminescent device of claim 1, wherein the polymer comprises a repeat unit represented by Chemical Formula 4, a repeat unit represented by Chemical Formula 5, or a combination thereof: 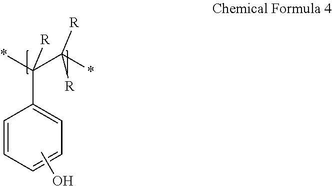
wherein * is a portion linked to an adjacent repeat unit, R are the same or different and each independently is hydrogen or a substituted or unsubstituted C1 to C30 alkyl group, and optionally the benzene ring is unsubstituted or further substituted; 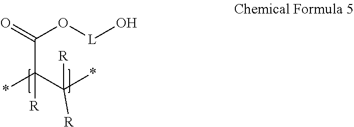
wherein R are the same or different and each independently is hydrogen or a substituted or unsubstituted C1 to C30 alkyl group, L is a substituted or unsubstituted C1 to 10 alkylene group, and
* is a portion linked to an adjacent repeat unit.

7. The electroluminescent device of claim 6, wherein the polymer has a solubility in a C1 to C5 alcohol of greater than or equal to about 3 g/L and less than or equal to about 1000 g/L.

8. The electroluminescent device of claim 1, wherein a weight average molecular weight of the polymer is greater than or equal to about 500 g/mol and less than or equal to about 500,000 g/mol.

9. The electroluminescent device of claim 1, wherein a weight average molecular weight of the polymer is greater than or equal to about 1000 g/mol and less than or equal to about 100,000 g/mol, and
wherein the polymer has a solubility in water or alcohol of greater than or equal to about 10 g/L and less than or equal to about 500 g/L, or the polymer has a pH of greater than or equal to about 5 and less than or equal to about 8.5.

10. The electroluminescent device of claim 1, wherein a thickness of the organic layer is greater than or equal to about 10 nm and less than or equal to about 100 micrometers.

11. The electroluminescent device of claim 1, wherein the organic layer is spaced apart from the electron transport layer and the second electrode and is disposed to face the electron transport layer or the second electrode.

12. The electroluminescent device of claim 1, wherein the light emitting layer is configured to emit a first light, and
wherein the second electrode has a thickness of greater than or equal to about 11 nm and less than or equal to about 50 nm, and is configured to exhibit a light transmittance of 20% or more for the first light, and
the first electrode is configured to reflect at least a portion of the first light.

13. The electroluminescent device of claim 1, wherein the metal oxide nanoparticle comprise zinc; and an alkali metal, an alkali earth metal, Zr, W, Li, Ti, Y, Al, Ga, In, Sn, Co, V, or a combination thereof.

14. A display device comprising the electroluminescent device of claim 1.

15. A method of making an electroluminescent device of claim 1, the method comprising:
forming the light emitting layer including the semiconductor nanoparticle on the first electrode;
forming the electron transport layer including the metal oxide nanoparticle on the light emitting layer;
forming a thin film conductor on the electron transport layer to obtain a stacked structure; and
conducting a post-treatment of the stacked structure,
wherein the post-treatment comprises;
positioning at least a portion of the stacked structure with the polymer in a first space;
maintaining the first space at a post-treatment temperature of greater than or equal to about 40° C. and less than or equal to about 200° C.; and
wherein the at least a portion of the stacked structure comprises the electron transport layer and the thin film conductor.

16. The method of claim 15,
further comprising applying an organic layer-forming composition including the polymer and a liquid vehicle onto the electron transport layer or the second electrode; and
optionally wherein the liquid vehicle comprises water, C1-10 alcohol, a sulfoxide solvent, a nitrile solvent, an ester solvent, or a combination thereof.

17. The method of claim 15, wherein the first space is a container, and applying an organic layer-forming composition including the polymer and a liquid vehicle to a first surface of the container, wherein the first surface is directed to the electron transport layer or the second electrode; and optionally wherein the liquid vehicle comprises water, C1-10 alcohol, a sulfoxide solvent, a nitrile solvent, an ester solvent, or a combination thereof.

18. The method of claim 15, wherein the polymer comprises a polyvinyl alcohol, a polyvinyl phenol, a polyhydroxyalkyl(meth)acrylate, a polyhydroxyalkyl(meth)acrylamide, or a combination thereof.

19. The method of claim 15, wherein a weight average molecular weight of the polymer is greater than or equal to about 500 g/mol and less than or equal to about 500,000 g/mol;
wherein the polymer has a solubility of greater than or equal to about 1 g/L and less than or equal to about 1000 g/L; or
wherein the polymer is configured to exhibit a pH of greater than or equal to about 4.5 and less than or equal to about 8.5.

20. The method of claim 15,
wherein the post treatment temperature is greater than or equal to about 50° C. and less than or equal to about 120° C., and
a time for the post treatment is greater than or equal to about 10 minutes and less than or equal to about 10 days.
